(19) United States
(12) Patent Application Publication
(10) Pub. No.: US 2005/0100814 A1
(43) Pub. Date: May 12, 2005

(54) Bases and surfactants and their use in photoresist compositions for microlithography

(76) Inventors: Larry L. Berger, Chadds Ford, PA (US); Michael Karl Crawford, Glens Mills, PA (US); Frank L. Schadt III, Wilmington, DE (US); Frederick Claus Zumsteg Jr, Wilmington, DE (US)

Correspondence Address: Jessica M Sinnott;E I du Pont de Nemours & Company, Legal Patents, Wilmington, DE, 19898, US

(21) Appl. No.: 10/399,375

(22) PCT Filed: Nov. 26, 2001
(86) PCT No.: PCT/US01/44294

Related U.S. Application Data
(60) Provisional application No. 60/253,820, filed on Nov. 29, 2000.

(51) Int. Cl. G03F 7/00; G03F 7/20; G03F 7/004; G03F 7/30

(52) U.S. Cl. 430/270.1; 430/311; 430/281.1; 430/326; 526/72; 526/242; 526/250; 525/328.8

(57) ABSTRACT

A photoresist composition having: (A) a polymer selected from the group consisting of: (a) a fluorine-containing copolymer having a repeat unit derived from at least one ethylenically unsaturated compound characterized in that at least one ethylenically unsaturated compound is polycyclic; (b) a branched polymer containing protected acid groups, said polymer comprising one or more branch segment(s) chemically linked along a linear backbone segment; (c) fluoropolymers having at least one fluoroalcohol group having the structure: —C(R_{f})(R_{f}′)OH, wherein R_{f} and R_{f}′ are the same or different fluoroalkyl groups of from 1 to about 10 carbon atoms or taken together are (CF₂)ₙ wherein n is 2 to 10; (d) amorphous vinyl homopolymers of perfluoro(2,2-dimethyl-1,3-dioxole) or CX₂═CY₂ where X═F or CF₃ and Y═—H or amorphous vinyl copolymers of perfluoro(2,2-dimethyl-1,3-dioxole) and CX₂═CY₂; and (e) nitrile/fluoroalcohol-containing polymers prepared from substituted or unsubstituted vinyl ethers; (B) at least one photoactive component; and (C) a functional compound selected from the group consisting of a base and a surfactant. The polymer may have an absorption coefficient of less than about 5.0^{m?-1} at a wavelength of about 157 nm. These photoresist compositions have improved imaging properties.

### BACKGROUND OF THE INVENTION

1. Field of the Invention

The present invention pertains to photoimaging and, in particular, the use of photoresists (positive-working and/or negative-working) for imaging in the production of semiconductor devices. The present invention also pertains to novel bases and surfactants that may be used with polymer compositions having high UV transparency (particularly at short wavelengths, e.g., 157 nm and 193 nm) and that are useful in photoresists and potentially in many other applications.

2. Background of the Invention

Polymer products are used as components of imaging and photosensitive systems and particularly in photoimaging systems such as those described in Introduction to Microlithography, Second Edition by L. F. Thompson, C. G. Willson, and M. J. Bowden, American Chemical Society, Washington, D.C., 1994. In such systems, ultraviolet (UV) light or other electromagnetic radiation impinges on a material containing a photoactive component to induce a physical or chemical change in that material. A useful or latent image is thereby produced which can be processed into a useful image for semiconductor device fabrication.

Although the polymer product itself may be photoactive, generally a photosensitive composition contains one or more photoactive components in addition to the polymer product. Upon exposure to electromagnetic radiation (e.g., UV light), the photoactive component acts to change the Theological state, solubility, surface characteristics, refractive index, color, electromagnetic characteristics or other such physical or chemical characteristics of the photosensitive composition as described in the Thompson et al. publication supra.

For imaging very fine features at the submicron level in semiconductor devices, electromagnetic radiation in the far or extreme ultraviolet (UV) is needed. Positive working resists generally are utilized for semiconductor manufacture. Lithography in the UV at 365 nm (I-line) using novolak polymers and diazonaphthoquinones as dissolution inhibitors is a currently established chip technology having a resolution limit of about 0.35-0.30 micron. Lithography in the far UV at 248 nm using p-hydroxystyrene polymers is known and has a resolution limit of 0.35-0.18 nm. There is strong impetus for future photolithography at even shorter wavelengths, due to a decreasing lower resolution limit with decreasing wavelength (i.e., a resolution limit of 0.18-0.12 micron for 193 nm imaging and a resolution limit of about 0.07 micron for 157 nm imaging). Photolithography using 193 nm exposure wavelength (obtained from an argon fluorine (ArF) excimer laser) is a leading candidate for future microelectronics fabrication using 0.18 and 0.13 μm design rules. Photolithography using 157 nm exposure wavelength (obtained from a fluorine excimer laser) is a leading candidate for future microlithography further out on the time horizon (beyond 193 nm) provided suitable materials can be found having sufficient transparency and other required properties at this very short wavelength. The opacity of traditional near UV and far UV organic photoresists at 193 nm or shorter wavelengths precludes their use in single-layer schemes at these short wavelengths. A need, however, exists for resist compositions that satisfy the myriad of requirements for single layer photoresists that include optical transparency at 193 nm and/or 157 nm, plasma etch resistance, and solubility in an aqueous base developer, and still meet the increasingly demanding imaging properties required.

In positive tone photoresists, there is a continual need for improved resolution. It has been previously found for such chemically amplified resists that addition of small amounts of a base can significantly improve various imaging properties, such as resolution, image profile, depth of focus, and processing latitude. This is thought to occur by controlling the diffusion of acid, generated by exposure of the photoacid generator, into unexposed or poorly exposed areas. It has also been previously been found that surfactants added to the resist formulation can improve the coatability and/or developability of such resist compositions leading to improved imaging properties.

### SUMMARY OF THE INVENTION

This invention combines the use of a base and/or surfactant in a photoresist formulation with materials found to be optically transparent at low wavelengths, typically at or below about 193 nm, more typically at or below about 157 nm.

In a first aspect, the invention provides a photoresist composition comprising:
(A) at least one polymer selected from the group consisting of:
   (a) a fluorine-containing copolymer comprising a repeat unit derived from at least one ethylenically unsaturated compound characterized in that the at least one ethylenically unsaturated compound is polycyclic;
   (b) a branched polymer containing protected acid groups, said polymer comprising one or more branch segment(s) chemically linked along a linear backbone segment;
   (c) a fluoropolymer having at least one fluoroalcohol group having the structure:
      —C(R_{f})(R_{f}′)OH
wherein R_{f} and R_{f}′ are the same or different fluoroalkyl groups of from 1 to about 10 carbon atoms or taken together are (CF₂)ₙ wherein n is 2 to about 10;
   (d) an amorphous vinyl homopolymer of perfluoro(2,2-dimethyl-1,3-dioxole) or CX₂═CY₂ where X═F or CF₃ and Y═—H or an amorphous vinyl copolymer of perfluoro(2,2-dimethyl-1,3-dioxole) and CX₂═CY₂; and
   (e) a nitrile/fluoroalcohol-containing polymer prepared from a substituted or unsubstituted vinyl ether; and
(B) at least one photoactive component; and
(C) a functional compound selected from the group consisting of a base and a surfactant.

In a second aspect, the invention provides a process for preparing a photoresist image on a substrate comprising, in order:
(X) imagewise exposing the photoresist layer to form imaged and non-imaged areas, wherein the photoresist layer is prepared from a photoresist composition comprising:
   (A) at least one polymer selected from (a)-(e) described above;
   (B) a photoactive component; and
   (C) a functional compound selected from the group consisting of a base and a surfactant; and
(Y) developing the exposed photoresist layer having imaged and non-imaged areas to form the relief image on the substrate.

The base may have a pKₐ of about 5 or greater. The base may be selected from the group consisting of at least one monomeric nitrogen compound, a polymeric nitrogen compound, an organic amine, an organic ammonium hydroxide, and a salt thereof with an organic acid.

The surfactant may have a positive, negative, or neutral charge and may be selected from the group consisting of fluorinated or non-fluorinated surfactants.

### DETAILED DESCRIPTION OF THE PREFERRED EMBODIMENT(S)

The photoresist element comprises a support, and at least photoresist layer; wherein the photoresist layer is prepared from a photoresist composition comprises:
(A) a polymer selected from the group consisting of (a) to (e) as described above and mixtures thereof;
(B) a photoactive component; and (C) a functional compound selected from the group consisting of a base and a surfactant.

The (A) polymers are used as photoresist compositions for semiconductor lithography. In particular, since low optical absorption below 193 nm is a prime attribute of the materials of this invention, they should be of particularly utility at this wavelength. The polymers are not required to but may have an absorption coefficient of less than about 5.0 μm⁻¹ at a wavelength of about 157 nm, typically less than about 4.0 μm⁻¹ at this wavelength, and, more typically, less than about 3.5 μm⁻¹ at this wavelength.

(A) The Polymer:

The fluorine-containing copolymer (a) comprises a repeat unit derived from at least one ethylenically unsaturated compound characterized in that the at least one ethylenically unsaturated compound is polycyclic. Copolymer (a) is selected from the group consisting of:
(a1) a fluorine-containing copolymer comprising a repeat unit derived from at least one ethylenically unsaturated compound characterized in that at least one ethylenically unsaturated compound is polycyclic and at least one other ethylenically unsaturated compound contains at least one fluorine atom covalently attached to an ethylenically unsaturated carbon atom; and
(a2) a fluorine-containing copolymer comprising a repeat unit derived from at least one polycyclic ethylenically unsaturated compound containing at least one of a fluorine atom, perfluoroalkyl group, and perfluoroalkoxy group which is covalently attached to a carbon atom which is contained within a ring structure and separated from each ethylenically unsaturated carbon atom of the ethylenically unsaturated compound by at least one covalently attached carbon atom.

The at least one ethylenically unsaturated compound disclosed in (a1) may selected from the group consisting of: 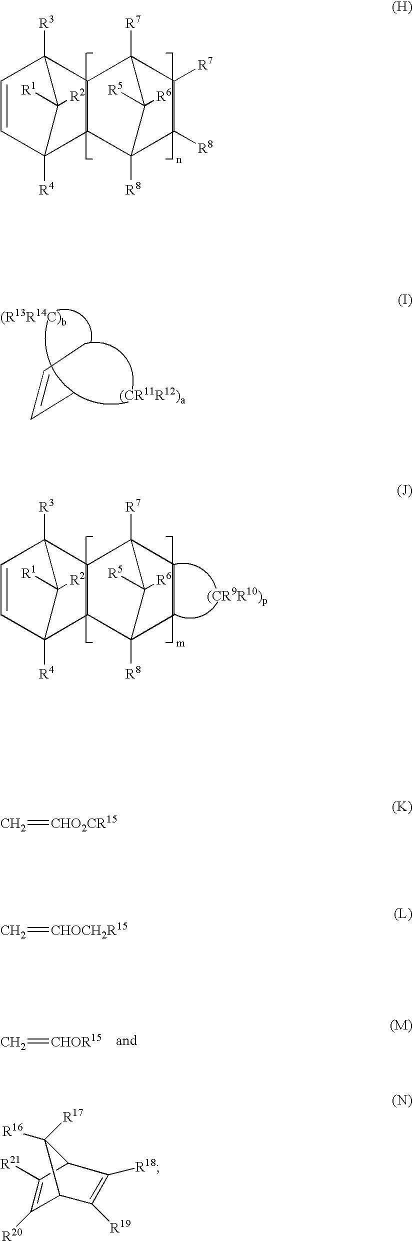
wherein:
each of m and n is 0, 1 or 2, p is an integer of at least 3;
a and b are independently 1 to 3 except that a is not=1 when b=2 or vice versa;
R¹ to R¹⁴ are the same or different and each represents a hydrogen atom, a halogen atom, a hydrocarbon group containing 1 to 14 carbon atoms, typically 1 to 10 carbon atoms optionally substituted with at least one O, N, S, P or halogen atom for example a carboxyl group such as a secondary or tertiary alkyl carboxylic acid group or carboxylic ester group;
R¹⁵ is a saturated alkyl group of about 4 to 20 carbon atoms, optionally containing one or more ether oxygens with the proviso that the ratio of carbon atoms to hydrogen atoms is greater than or equal to 0.58;
R¹⁶ to R²¹ are each independently hydrogen atoms, C₁ to C₁₂ alkyls, (CH₂)_{q}CO₂A, CO₂(CH₂)_{q}CO₂A or CO₂A wherein q is 1 to 12 and A is hydrogen or an acid protecting group with the proviso that at least one of R¹⁸ to R²¹ is CO₂A.

A key characteristic of the copolymers (and photoresists comprised of the copolymers) of this invention is the cooperative combination of polycyclic repeat unit(s) with the same or different repeat units that are fluorine containing and, furthermore, with all repeat units in the copolymers not containing aromatic functionality. The presence of polycyclic repeat units in the copolymers is important in order for the copolymers to possess high resistance to plasma etching (e.g., reactive ion etching). Polycyclic repeat units also tend to provide a high glass transition temperature which is important for maintaining dimensional stability in the resist films. The presence of repeat units that are fluorine-containing is important in order for the copolymers to possess high optical transparency, i.e., to have low optical absorptions in the extreme and far UV. The absence of aromatic functionality in the repeat units of the copolymers is also required in order for the polymers to possess high optical transparency.

In certain embodiments of this invention, the fluorine-containing copolymer may be comprised of a repeat unit derived from at least one polycyclic ethylenically unsaturated compound having at least one atom or group selected from the group consisting of fluorine atom, perfluoroalkyl group, and perfluoroalkoxy group, covalently attached to a carbon atom which is contained within a ring structure. Fluorine atoms, perfluoroalkyl groups and perfluoroalkoxy groups tend to inhibit polymerization of cyclic ethylenically unsaturated compounds by metal-catalyzed addition polymerization or metathesis polymerization when such groups are attached directly to an ethylenically unsaturated carbon atom. Thus, it is important in such cases that the at least one fluorine atom, perfluoroalkyl group and perfluoroalkoxy group be separated from each ethylenically unsaturated carbon atom of the ethylenically unsaturated compound by at least one covalently attached carbon atom. Furthermore, attaching the atom and/or group directly to a ring minimizes the presence of undesirable non-fluorinated aliphatic carbon atoms.

The copolymers of this invention surprisingly have balanced properties that are important for imparting necessary properties to photoresist compositions for semiconductor applications. First, these copolymers have unexpectedly low optical absorptions in the extreme and far UV, including 193 nm and 157 nm wavelengths. Having copolymers with low optical absorptions is important for formulating high photospeed resists wherein the major amount of UV light is absorbed by the photoactive component(s) and not lost due to absorption by the copolymer (matrix of the resist). Second, resists comprising the fluorine-containing polymers of this invention desirably exhibit very low plasma etch rates. This latter property is important in affording high resolution precision resists that are required in semiconductor fabrication. Achieving simultaneously suitable values of these properties is particularly important for imaging at 157 nm. In this case, ultra thin resists are needed for high resolution, but these thin resists must nevertheless be highly etch resistant such that resist remains on imaged substrates and protects areas of underlying substrate during etching.

In the preferred embodiments of this invention, the photoresist composition comprises copolymers that comprise a repeat unit derived from at least one polycyclic comonomer (i.e., a comonomer comprising at least two rings, e.g., norbornene). This is important for three main reasons: 1) polycyclic monomers have relatively high carbon to hydrogen ratios (C:H), which results in base polymers comprised of repeat units of these polycyclic monomers generally having good plasma etch resistance; 2) polymers having repeat units derived from polyclic monomers, which preferably can be fully saturated upon polymerization, generally have good transparency characteristics; and 3) polymers prepared from polycyclic monomers usually have relatively high glass transition temperatures for improved dimensional stability during processing. The ethylenically unsaturated group may be contained within the polycyclic moiety as in norbornene or may be pendant to the polycyclic moiety as in 1-adamantane carboxylate vinyl ester. A polymer comprised of repeat units derived from polycyclic comonomers, having high C:H ratios, has a relatively low Ohnishi number (O.N.), where:
O. N.=N/(N_{C}−N_{O})
with N being the number of atoms in the repeat unit of the polymer, N_{C} being the number of carbon atoms in the repeat unit of the polymer, and N_{O} being the number of oxygen atoms in the repeat unit of the polymer. There is an empirical law discovered by Ohnishi et al. (J. Electrochem. Soc., Solid-State Sci. Technol., 130, 143 (1983) which states that the reactive ion etch (RIE) rate of polymers is a linear function of the Ohnishi number (O.N.). As one example, poly(norbornene) has formula poly(C₇H₁₀) and the O.N.=17/7=2.42. Polymers comprised predominantly of carbon and hydrogen having polycyclic moieties and relatively little functionality containing oxygen will have relatively low O.N.s and will, according to the empirical law of Ohnishi, have corresponding low (in an approximate linear manner) RIE rates.

As is well known to those skilled in the polymer art, an ethylenically unsaturated compound undergoes free radical polymerization to afford a polymer having a repeat unit that is derived from the ethylenically unsaturated compound. Specifically, an ethylenically unsaturated compound having structure: 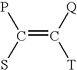
that undergoes free radical polymerization will afford a polymer having a repeat unit: 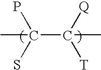
where P, Q, S, and T independently can represent, but are not limited to, H, F, Cl, Br, an alkyl group containing 1 to 14 carbon atoms, aryl, aralkyl group containing 6 to 14 carbon atoms or a cycloalkyl group containing 3 to 14 carbon atoms.

If only one ethylenically unsaturated compound undergoes polymerization, the resulting polymer is a homopolymer. If two or more distinct ethylenically unsaturated compounds undergo polymerization, the resulting polymer is a copolymer.

Some representative examples of ethylenically unsaturated compounds and their corresponding repeat units are given below:

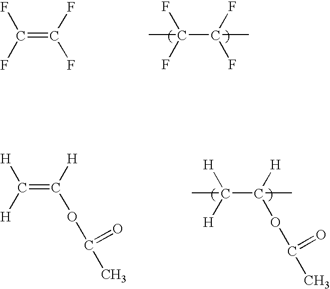

In the sections that follow, the photoresist compositions of this invention are described in terms of their component parts.

The photoresists of this invention comprise a fluorine-containing copolymer comprising a repeat unit derived from at least one ethylenically unsaturated compound characterized in that at least one ethylenically unsaturated compound is polycyclic and at least one ethylenically unsaturated compound contains at least one fluorine atom covalently attached to an ethylenically unsaturated carbon atom. Representative ethylenically unsaturated compounds that are suitable for the fluorine-containing copolymers of this invention include, but are not limited to, tetrafluoroethylene, chlorotrifluoroethylene, hexafluoropropylene, trifluoroethylene, vinylidene fluoride, vinyl fluoride, perfluoro-(2,2-dimethyl-1,3-dioxole), perfluoro-(2-methylene-4-methyl-1,3-dioxolane, CF₂═CFO(CF₂)ₜCF═CF₂, where t is 1 or 2, and R_{f}OCF═CF₂ wherein R_{f} is a saturated fluoroalkyl group of from 1 to about 10 carbon atoms. The fluorine-containing copolymers of this invention can be comprised of any integral number of additional fluorine-containing comonomers, which include, but are not limited to, those listed supra. Preferred comonomers are tetrafluoroethylene, chlorotrifluoroethylene, hexafluoropropylene, trifluoroethylene and R_{f}OCF═CF₂, wherein R_{f} is a saturated fluoroalkyl group of from 1 to about 10 carbon atoms. More preferred comonomers are tetrafluoroethylene, chlorotrifluoroethylene, hexafluoropropylene, and R_{f}OCF═CF₂, wherein R_{f} is a saturated perfluoroalkyl group of from 1 to about 10 carbon atoms. Most preferred comonomers are tetrafluoroethylene and chlorotrifluoroethylene.

Representative comonomers having structure H include, but are not limited to:

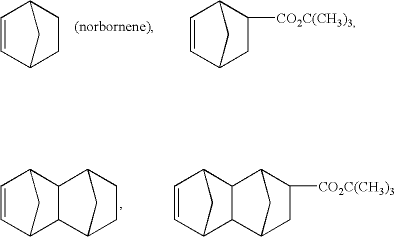

Representative comonomers having structure I include, but are not limited to:

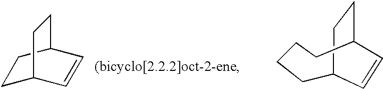

Representative comonomers having structure J include, but are not limited to:

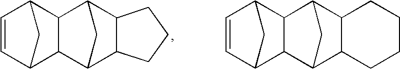

Representative comonomers having structure K include, but are not limited to:

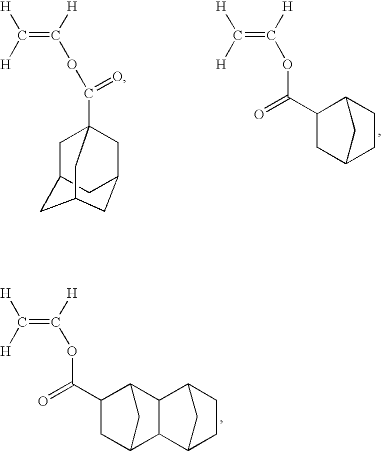

Representative comonomers having structure L include, but are not limited to:

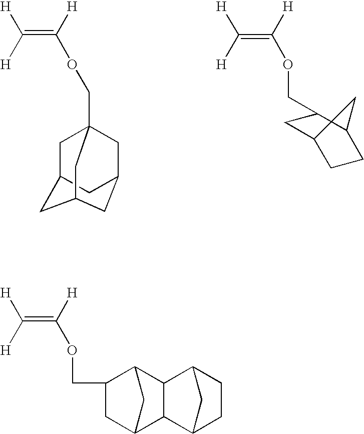

Representative comonomers having structure M include, but are not limited to:

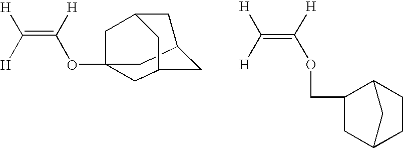

All of the inventive copolymers comprising comonomers having structures K, L and M are characterized as comprising fluorinated olefins and vinyl esters of formula CH₂═CHO₂CR²² or vinyl ethers of formulae CH₂═CHOCH₂R²² or CH₂═CHOR²², wherein R²² are hydrocarbon groups of about 4 to 20 carbon atoms with a C:H ratio that is relatively high and which is greater than 0.58 since a high C:H ratio corresponds to good plasma etch resistance. (This is in contrast to copolymers comprising fluorinated olefins and vinyl esters of formula CH₂═CHO₂CR²³ or vinyl ethers of formulae CH₂═CHOCH₂R²³ or CH₂═CHOR²³, wherein R²³ has a C:H ratio that is relatively low and which is less than 0.58. R²² and R²³ are selected from alkyl, aryl, aralkyl, and cycloalkyl.

Representative comonomers having structure N include, but are not limited to: 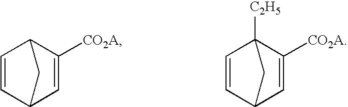
where A═H, (CH₃)₃C, (CH₃)₃Si.

In preferred embodiments described above having at least one unsaturated compound of structure H—N as the second recited comonomer, there is a limitation on the second comonomer if (and only if) the fluorine-containing copolymer is not comprised of additional comonomer(s) having functionality that is selected from a carboxylic acid and a protected acid group. In this case, the fluorine-containing copolymer has just two comonomers (the two recited comonomers and having no additional unrecited comonomers). In this case, there must be sufficient functionality that is selected from a carboxylic acid and a protected acid group present in the at least one unsaturated compound (i.e., the second recited comonomer) such that the photoresists of this invention that are comprised of the fluorine-containing polymer are developable upon imagewise exposure as explained in more detail infra. In these embodiments with the fluorine-containing copolymer having just two comonomers, the mole percentages of the two comonomers in the copolymer can range from 90%, 10% to 10%, 90% for the fluoromonomer (first recited monomer) and the second comonomer, respectively. Typically, the mole percentages of the two comonomers are in the range from 60%, 40% to 40%, 60% for the fluoromonomer (first recited monomer) and the second comonomer, respectively.

The fluorine-containing copolymers of this invention can be comprised of any integral number without limit of additional comonomers beyond the two recited comonomers (i.e., (i) at least one ethylenically unsaturated compound containing at least one fluorine atom covalently attached to an ethylenically unsaturated carbon atom; and (ii) at least one unsaturated compound selected from the group of structures H—N) for some embodiments. Representative additional comonomers can include, but are not limited to, acrylic acid, methacrylic acid, t-butyl acrylate, t-butyl methacrylate, t-amyl acrylate, t-amyl methacrylate, isobutyl acrylate, isobutyl methacrylate, ethylene, vinyl acetate, itaconic acid, and vinyl alcohol. In those embodiments where the fluorine-containing copolymer has two recited comonomers and is comprised of three or more comonomers, the mole percentage of the second recited comonomer (i.e., (ii) at least one unsaturated compound selected from the group of structures H—N) ranges from about 20 mole % to about 80 mole %, preferably ranges from about 30 mole % to about 70 mole %, more preferably ranges from about 40 mole % to about 70 mole %, and still most preferably is about 50 to about 70 mole %. Summation of the mole percentages of all other comonomers constituting the copolymer represents a balance that when added to the mole percentage of the second recited comonomer totals 100%. The sum of the mole percentages of all other comonomers present in the copolymer except for the second recited comonomer broadly is in the range from about 80 mole % to about 20 mole %. Preferably, the sum of the mole percentages of all other comonomers is in the range from about 70 mole % to about 30 mole %. More preferably, the sum of the mole percentages of all other comonomers is in the range from about 60 mole % to about 30 mole %, and, still more preferably, the sum of the mole percentages of all other comonomers is in the range from about 50 mole % to about 30 mole %. When the fluorine-containing polymer is a terpolymer, a suitable ratio of the fluoromonomer (first recited monomer) to the additional comonomer can broadly range from 5:95 to 95:5. When the fluorine-containing copolymer contains additional comonomers having functionality of acid groups or protected acid groups in sufficient amounts necessary for developability, the functionality can be present or absent in the second recited comonomer without limitation.

A given fluorine-containing copolymer, comprised of a repeat unit derived from a comonomer having at least one fluorine atom attached to an ethylenically unsaturated carbon atom, of the photoresist composition(s) of this invention can be prepared by free radical polymerization. Polymers may be prepared by bulk, solution, suspension or emulsion polymerization techniques known to those skilled in the art using free radical initiators, such as azo compounds or peroxides.

A given fluorine-containing copolymer, containing only repeat units derived from all cyclic comonomers and totally lacking a repeat unit derived from a comonomer that has one or more fluorine atom(s) attached to an ethylenically unsaturated carbon atom(s), of the photoresist composition(s) of this invention can also be prepared by free radical polymerization, but in addition can be prepared by other polymerization methods, including vinyl-addition polymerization and ring-opening methathesis polymerization (ROMP). Both of the latter polymerization methods are known to those skilled in the art. Vinyl-addition polymerization using nickel and palladium catalysts is disclosed in the following references: 1) Okoroanyanwu U.; Shimokawa, T.; Byers, J. D.; Willson, C. G. J. Mol. Catal. A: Chemical 1998, 133, 93; 2) PCT WO 97/33198 (Sep. 12, 1997) assigned to B.F. Goodrich; 3) Reinmuth, A.; Mathew, J. P.; Melia, J.; Risse, W. Macromol. Rapid Commun. 1996, 17, 173; and 4) Breunig, S.; Risse, W. Makromol. Chem. 1992, 193, 2915. Ring-opening metathesis polymerization is disclosed in references 1) and 2) supra using ruthenium and irridium catalysts; and also in 5) Schwab, P.; Grubbs, R. H.; Ziller, J. W. J. Am. Chem. Soc. 1996, 118, 100; and 6) Schwab, P.; France, M. B.; Ziller, J. W.; Grubbs, R. H. Angew. Chem. Int Ed. Engl. 1995, 34, 2039.

Some of the fluorine-containing bipolymers of the resist compositions of this invention, where the bipolymer contains a fluoromonomer (e.g., TFE) and a cyclic olefin (e.g., norbornene) appear to be alternating or approximately alternating bipolymers having a structure, but not limited to, the one shown below:

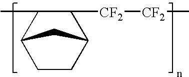

In such cases, the invention includes these alternating or approximately alternating copolymers but is not in any manner limited to just alternating copolymer structures.

These polymers are described in WO 00/17712 published on Mar. 20, 2000.

The polymer (b) is a branched polymer containing protected acid groups, said polymer comprising one or more branch segment(s) chemically linked along a linear backbone segment. The branched polymer can be formed during free radical addition polymerization of at least one ethylenically unsaturated macromer component and at least one ethylenically unsaturated comonomer. The ethylenically unsaturated macromer component has a number average molecular weight (Mₙ) between a few hundred and 40,000 and the linear backbone segment resulting from the polymerization has a number average molecular weight (Mₙ) between about 2,000 and about 500,000. The weight ratio of the linear backbone segment to the branch segment(s) is within a range of about 50/1 to about 1/10, and preferably within the range of about 80/20 to about 60/40. Typically the macromer component has a number average molecular weight (Mₙ) from 500 to about 40,000 and more typically of about 1,000 to about 15,000. Typically such an ethylenically unsaturated macromer component can have a number average molecular weight (Mₙ) equivalent to there being from about 2 to about 500 monomer units used to form the macromer component and typically between 30 and 200 monomer units.

In a typical embodiment, the branched polymer contains from 25% to 100% by weight of compatibilizing groups, i.e., functional groups present to increase compatibility with the photoacid generator, preferably from about 50% to 100% by weight, and more preferably from about 75% to 100% by weight. Suitable compatibilizing groups for ionic photoacid generators include, but are not limited to, both non-hydrophilic polar groups and hydrophilic polar groups. Suitable non-hydrophilic polar groups include, but are not limited to, cyano (—CN) and nitro (—NO₂). Suitable hydrophilic polar groups include, but are not limited to protic groups such as hydroxy (OH), amino (NH₂), ammonium, amido, imido, urethane, ureido, or mercapto; or carboxylic (CO₂H), sulfonic, sulfinic, phosphoric, or phosphoric acids or salts thereof. Preferably, compatibilizing groups are present in the branch segment(s).

Typically, the protected acid groups (described infra) produce carboxylic acid groups after exposure to UV or other actinic radiation and subsequent post-exposure baking (i.e., during deprotection). The branched polymer present in the photosensitive compositions of this invention, typically will contain between about 3% to about 40% by weight of monomer units containing protected acid groups, preferably between about 5% to about 50%, and more preferably between about 5% to about 20%. The branch segments of such a preferred branched polymer typically contain between 35% to 100% of the protected acid groups present. Such a branched polymer when completely unprotected (all protected acid groups converted to free acid groups) has an acid number between about 20 and about 500, preferably between about 30 and about 330, and more preferably between about 30 and about 130, and analogously the ethylenically unsaturated macromer component preferably has an acid number of about 20 and about 650, more preferably between about 90 and about 300 and the majority of the free acid groups are in the branch segments.

Each photosensitive composition of this aspect of the invention contains a branched polymer, also known as a comb polymer, which contains protected acid groups. The branched polymer has branch segments, known as polymer arms, of limited molecular weight and limited weight ratio relative to a linear backbone segment. In a preferred embodiment, a majority of the protected acid groups are present in the branch segments. The composition also contains a component, such as a photoacid generator, which renders the composition reactive to radiant energy, especially to radiant energy in the ultraviolet region of the electromagnetic spectrum and most especially in the far or extreme ultraviolet region.

In a specific embodiment, the branched polymer comprises one or more branch segments chemically linked along a linear backbone segment wherein the branched polymers have a number average molecular weight (Mₙ) of about 500 to 40,000. The branched polymer contains at least 0.5% by weight of branch segments. The branch segments, also known as polymer arms, typically are randomly distributed along the linear backbone segment. The “polymer arm” or branch segment is a polymer or oligomer of at least two repeating monomer units, which is attached to the linear backbone segment by a covalent bond. The branch segment, or polymer arm, can be incorporated into the branched polymer as a macromer component, during the addition polymerization process of a macromer and a comonomer. A “macromer” for the purpose of this invention, is a polymer, copolymer or oligomer of molecular weight ranging from several hundred to about 40,000 containing a terminal ethylenically unsaturated polymerizable group. Preferably the macromer is a linear polymer or copolymer end capped with an ethylenic group. Typically, the branched polymer is a copolymer bearing one or more polymer arms, and preferably at least two polymer arms, and is characterized in that between about 0.5 and about 80 weight %, preferably between about 5 and 50 weight % of the monomeric components used in the polymerization process is a macromer. Typically, comonomer components used along with the macromer in the polymerization process likewise contain a single ethylenic group that can copolymerize with the ethylenically unsaturated macromer.

The ethylenically unsaturated macromer and the resulting branch segment of the branched polymer, and/or the backbone of the branched polymer, can have bonded thereto one or more protected acid groups. For the purposes of this invention, a “protected acid group” means a functional group which, when deprotected, affords free acid functionality that enhances the solubility, swellability, or dispersibility in aqueous environments, of the macromer and/or the branched polymer to which it is bonded. The protected acid group may be incorporated into the ethylenically unsaturated macromer and the resulting branch segment of the branched polymer, and/or the backbone of the branched polymer, either during or after their formation. While addition polymerization using a macromer and at least one ethylenically unsaturated monomer is preferred for forming the branched polymer, all known methods of preparing branched polymers using either addition or condensation reactions can be utilized in this invention. Furthermore, use of either preformed backbones and branch segments or in situ polymerized segments are also applicable to this invention.

The branch segments attached to the linear backbone segment can be derived from ethylenically unsaturated macromers prepared according to the general descriptions in U.S. Pat. No. 4,680,352 and U.S. Pat. No. 4,694,054. Macromers are prepared by free radical polymerization processes employing a cobalt compound as a catalytic chain transfer agent and particularly a cobalt(II) compound. The cobalt(II) compound may be a pentacyanocobalt(II) compound or a cobalt(II) chelate of a vicinal iminobydroxyimino compound, a dihydroxyimino compound, a diazadihydroxyiminodialkyldecadiene, a diazadihydroxyimnino-dialkylundecadiene, a tetraazatetraalkylcyclotetradecatetraene, a tetraazatetraalkylcyclotedodecatetraene, a bis(difluoroboryl)diphenyl glyoximato, a bis(difluoroboryl)dimethyl glyoximato, a N,N′-bis(salicylidene)ethylenediamine, a dialkyldiaza-dioxodialkyldodecadiene, or a dialkyldiazadioxodialkyl-tridecadiene. Low molecular weight methacrylate macromers may also be prepared with a pentacyanocobalt(II) catalytic chain transfer agent as disclosed in U.S. Pat. No. 4,722,984.

Illustrative macromers using this approach are methacrylate polymers with acrylates or other vinyl monomers wherein the polymers or copolymers have a terminal ethylenic group and a hydrophilic functional group. Preferred monomer components for use in preparing macromers include: tertiary-butyl methacrylate (tBMA), tertiary-butyl acrylate (tBA), methyl methacrylate (MMA); ethyl methacrylate (EMA); butyl methacrylate (BMA); 2-ethylhexyl methacrylate; methyl acrylate (MA); ethyl acrylate (EA); butyl acrylate (BA); 2-ethylhexyl acrylate; 2-hydroxyethyl methacrylate (HEMA); 2-hydroxyethyl acrylate (HEA); methacrylic acid (MA); acrylic acid (AA); esters of acrylic and methacrylic acid wherein the ester group contains from 1 to 18 carbon atoms; nitriles and amides of acrylic and methacrylic acid (e.g., acrylonitrile); glycidyl methacrylate and acrylate; itaconic acid (IA) and itaconic acid anhydride (ITA), half ester and imide; maleic acid and maleic acid anhydride, half ester and imide; aminoethyl methacrylate; t-butyl aminoethyl methacrylate; dimethyl aminoethyl methacrylate; diethyl aminoethyl methacrylate; aminoethyl acrylate; dimethyl aminoethyl acrylate; diethyl aminoethyl acrylate; acrylamide; N-t-octyl acrylamide; vinyl methyl ether; styrene (STY); alpha-methyl styrene (AMS); vinyl acetate; vinyl chloride; and the like.

Itaconic acid anhydride (ITA, 2-methylenesuccinic anhydride, CAS No.=2170-03-8) is a particularly advantageous comonomer for use in the branched polymer since it has two active functional groups in the anhydride form, which become three upon ring opening to afford, diacid. The ethylenically unsaturated moiety is a first functional group, which provides capability for this comonomer to be incorporated into a copolymer by, for example, free radical polymerization. The anhydride moiety is a second functional group that is capable of reacting with a variety of other functional groups to afford covalently bonded products. An example of a functional group that an anhydride moiety can react with is a hydroxy group in an alcohol to form an ester linkage. Upon reaction of the anhydride moiety of ITA with a hydroxy group, there is formed an ester linkage and a free carboxyic acid moiety, which is a third functional group. The carboxylic acid functional group is useful in imparting aqueous processability to the resists of this invention. If a PAG is utilized having a hydroxy group, it is possible, as illustrated in some of the examples, to covalently link (tether) a PAG (or other photoactive components) to a branched polymer comprised of ITA comonomer or the like via this type of ester linkage (or other covalent linkages, such as amide, etc.).

The branched polymer may be prepared by any conventional addition polymerization process. The branched polymer, or comb polymer, may be prepared from one or more compatible ethylenically unsaturated macromer components and one or more compatible, conventional ethylenically unsaturated comonomer component(s). Preferred addition polymerizable, ethylenically unsaturated comonomer components are acrylates, methacrylates, and styrenics as well as mixtures thereof. Suitable addition polymerizable, ethylenically unsaturated comonomer components include: tertiary-butyl methacrylate (tBMA), tertiary-butyl acrylate (tBA), methyl methacrylate (MMA); ethyl methacrylate (EMA); butyl methacrylate (BMA); 2-ethylhexyl methacrylate; methyl acrylate (MA); ethyl acrylate (EA); butyl acrylate (BA); 2-ethylhexyl acrylate; 2-hydroxyethyl methacrylate (HEMA); 2-hydroxyethyl acrylate (HEA); methacrylic acid (MAA); acrylic acid (AA); acrylonitrile (AN); methacrylonitrile (MAN); itaconic acid {IA) and itaconic acid anhydride (ITA), half ester and imide; maleic acid and maleic acid anhydride, half ester and imide; aminoethyl methacrylate; t-butyl aminoethyl methacrylate; dimethyl aminoethyl methacrylate; diethyl aminoethyl methacrylate; aminoethyl acrylate; dimethyl aminoethyl acrylate; diethyl aminoethyl acrylate; acrylamide; N-t-octyl acrylamide; vinyl methyl ethers; styrene (S); alpha-methyl styrene; vinyl acetate; vinyl chloride; and the like. The majority of the copolymerizable monomer must be acrylate or styrenic or copolymers of these monomers with acrylates and other vinyl monomers.

Each constituent linear backbone segment and/or branch segment of the branched polymer of this invention may contain a variety of functional groups. A “functional group” is considered to be any moiety capable of being attached to a backbone segment or a branch segment by a direct valence bond or by a linking group. Illustrative of functional groups which can be borne by the backbone segment or the branch segments are —COOR²⁴; —OR²⁴; —SR²⁴ wherein R²⁴ can be hydrogen, alkyl group having 1 to 12 carbon atoms; cycloalkyl group of 3-12 carbon atoms; aryl, alkaryl or aralkyl group having 6 to 14 carbon atoms; a heterocyclic group containing 3 to 12 carbon atoms and additionally containing at least one S, O, N or P atom; or —OR²⁷ where R²⁷ can be alkyl of 1-12 carbon atoms, aryl, alkaryl or aralkyl group having 6 to 14 carbon atoms; —CN; —NR²⁵R²⁶ or 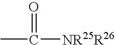
wherein R²⁵ and R²⁶ can be hydrogen, alkyl group having 1 to 12 carbon atoms; cycloalkyl group having of 3-12 carbon atoms; aryl, alkaryl, aralkyl of 6 to 14 carbon atoms; —CH₂OR²⁸ wherein R²⁸ is hydrogen, alkyl of 1 to 12 carbon atoms; or cycloalkyl of 3-12 carbon atoms, aryl, alkaryl, aralkyl having 6 to 14 carbon atoms, or together R²⁵ and R²⁶ can form a heterocyclic ring having 3 to 12 carbon atoms and containing at least one S, N, O or P; 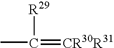
wherein R²⁹, R³⁰ and R³¹ can be hydrogen, alkyl of 1 to 12 carbon atoms or cycloalkyl of 3-12 carbon atoms; aryl, alkaryl, aralkyl of 6 to 14 carbon atoms, or —COOR²⁴ or when taken together R²⁹, R³⁰ and/or R³¹ can form a cyclic group; —SO₃H; a urethane group; an isocyanate or blocked isocyanate group; a urea group; an oxirane group; an aziridine group; a quinone diazide group; an azo group; an azide group; a diazonium group; an acetylacetoxy group; —SiR³²R³³R³⁴ wherein R³², R³³ and R³⁴ can be alkyl having 1-12 carbon atoms or cycloalkyl of 3-12 carbon atoms or —OR³⁵ where R³⁵ is alkyl of 1-12 carbon atoms or cycloalkyl of 3-12 carbon atoms; aryl, alkaryl or aralkyl of 6 to 14 carbon atoms; or an —OSO₃R³⁶, —OPO₂R³⁶, —PO₂R³⁶, —P R³⁶R³⁷R³⁸, —OPOR³⁶, —SR³⁶R³⁷, or —N+R³⁶R³⁷R³⁸ group (where R³⁶, R³⁷, and R³⁸ can be hydrogen, alkyl of 1 to 12 carbon atoms or cycloalkyl of 3-12 carbon atoms; aryl, alkaryl or aralkyl of 6 to 14 carbon atoms; or a salt or onium salt of any of the foregoing. Preferred functional groups are —COON, —OH, —NH₂, an amide group, a vinyl group, a urethane group, an isocyanate group, a blocked isocyanate group or combinations thereof. Functional groups may be located anywhere on the branched polymer. However, it is sometimes desirable to choose comonomers which impart bulk polymer characteristics to the linear backbone segment of the branched polymer and macromers which impart physical and chemical functionality to the branch segments in addition to hydrophilicity, such as solubility, reactivity, and the like.

In certain preferred embodiments of this invention, the branched polymer contains functional groups that are compatible with the photoacid generator, said functional groups being distributed in the branched polymer such that 25 to 100% of the functional groups are present in the segment of the branched polymer containing a majority of the protected acid groups. These functional groups are desirable since having enhanced compatibility of the photoacid generator with the branched polymer segmented having the majority of protected acid groups results in higher photospeed and perhaps higher resolution and/or other desirable properties of resists comprised of these branched polymer(s) having these functional groups to promote compatibility. For an ionic PAG, such as a triarylsulfonium salt, functional groups that promote compatibility include, but are not limited to, polar non-hydrophilic groups (e.g., nitro or cyano) and polar hydrophilic groups (e.g., hydroxy, carboxyl). For a nonionic PAG, such as structure III infra, preferred functional groups for imparting compatibility are less polar than the polar groups listed above. For the latter case, suitable functional groups include, but are not limited to, groups which impart rather similar chemical and physical properties to those of the non-ionic PAG. As two specific examples, aromatic and perfluoroalkyl functional groups are effective in promoting compatibility of the branched polymer with a nonionic PAG, such as structure III given infra.

In some preferred embodiments, the branched polymer is an acrylic/methacrylic/styrenic copolymer being at least 60% by weight acrylate and having at least 60% of methacrylate repeat units present either in a first location or a second location, the first location being one of the segments (i.e., branch segment(s) or linear backbone segment), the second location being a segment different from the first location, wherein at least 60% of the acrylate repeat units are present in the second location.

In some embodiments, the branched polymer is a fluorine-containing graft copolymer comprising a repeat unit derived from at least one ethylenically unsaturated compound containing at least one fluorine atom covalently attached to an ethylenically unsaturated carbon atom. The repeat unit bearing at least one fluorine atom can be either in the linear polymer backbone segment or in the branch polymer segment(s); preferably, it is in the linear polymer backbone segment. Representative ethylenically unsaturated compounds that are suitable for the fluorine-containing graft copolymers of this invention include, but are not limited to, tetrafluoroethylene, chlorotrifluoroethylene, hexafluoropropylene, trifluoroethylene, vinylidene fluoride, vinyl fluoride, and R_{f}OCF═CF₂ wherein R_{f} is a saturated perfluoroalkyl group of from 1 to about 10 carbon atoms. The fluorine-containing copolymers of this invention can be comprised of any integral number of additional fluorine-containing comonomers, which include, but are not limited to, those listed supra. Preferred comonomers are tetrafluoroethylene, chlorotrifluoroethylene, hexafluoropropylene, trifluoroethylene and R_{f}OCF═CF₂, wherein R_{f} is a saturated perfluoroalkyl group of from 1 to about 10 carbon atoms. More preferred comonomers are tetrafluoroethylene, chlorotrifluoroethylene, hexafluoropropylene, and R_{f}OCF═CF₂, wherein R_{f} is a saturated perfluoroalkyl group of from 1 to about 10 carbon atoms. Most preferred comonomers are tetrafluoroethylene and chlorotrifluoroethylene.

In some preferred embodiments, the fluorine-containing graft copolymer is further comprised of a repeat unit derived from at least one unsaturated compound selected from the group consisting of structures shown for polymer (a) above.

In one embodiment of this invention, a PAG is covalently linked (i.e., tethered) to the fluorine-containing graft copolymer to afford a photoresist.

In some preferred embodiments, the branched polymer is a fluorine-containing copolymer comprising a repeat unit derived from at least one ethylenically unsaturated compound containing a fluoroalcohol functional group having the structure:
—C(R_{f})(R_{f}′)OH
wherein R_{f} and R_{f}′ are the same or different fluoroalkyl groups of from 1 to about 10 carbon atoms or taken together are (CF₂)ₙ wherein n is 2 to 10.

A given fluorine-containing branched copolymer comprising a repeat unit derived from at least one ethylenically unsaturated compound containing a fluoroalcohol functional group according to this invention can have fluoroalkyl groups present as part of the fluoroalcohol functional group. These fluoroalkyl groups are designated as R_{f} and R_{f}′, which can be partially fluorinated alkyl groups or fully fluorinated alkyl groups (i.e., perfluoroalkyl groups). Broadly, R_{f} and R_{f}′ are the same or different fluoroalkyl groups of from 1 to about 10 carbon atoms or taken together are (CF₂)ₙ wherein n is 2 to 10. (In the last sentence, the terms “taken together” indicate that R_{f} and R_{f}′ are not separate, discrete fluorinated alkyl groups, but that together they form a ring structure such as is illustrated below in case of a 5-membered ring: 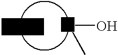
R_{f} and R_{f}′ can be partially fluorinated alkyl groups without limit according to the invention except that there must be a sufficient degree of fluorination present to impart acidity to the hydroxyl (—OH) of the fluoroalcohol functional group, such that the hydroxyl proton is substantially removed in basic media, such as in aqueous sodium hydroxide solution or tetraalkylammonium hydroxide solution. In preferred cases according to the invention, there will be sufficient fluorine substitution present in the fluorinated alkyl groups of the fluoroalcohol functional group such that the hydroxyl group will have a pKa value as follows: 5<pKa<11. Preferably, R_{f} and R_{f}′ are independently perfluoroalkyl group of 1 to 5 carbon atoms, and, most perferably, R_{f} and R_{f}′ are both trifluoromethyl (CF₃). Preferably, each fluorine-containing copolymer according to this invention has an absorption coefficient of less than 4.0 μm⁻¹ at a wavelength of 157 nm, preferably of less than 3.5 μm⁻¹ at this wavelength, and, more preferably, of less than 3.0 μm⁻¹ at this wavelength.

The fluorinated polymers, photoresists, and processes of this invention that include a fluoroalcohol functional group may have the structure:
—ZCH₂C(R_{f})(R_{f}′)OH
wherein R_{f} and R_{f}′ are the same or different fluoroalkyl groups of from 1 to about 10 carbon atoms or taken together are (CF₂)ₙ wherein n is 2 to 10; Z is selected from the group consisting of at least one of oxygen, sulfur, nitrogen, phosphorous, other Group VA element, and other Group VIA element. By the terms “other Group VA element” and “other Group VIA element”, these terms are understood to mean herein any other element in one of these groups of the periodic table that is other than the recited elements (i.e., oxygen, sulfur, nitrogen, phosphorous) in these groups. Oxygen is the preferred Z group.

Some illustrative, but nonlimiting, examples of representative comonomers containing a fluoroalcohol functional group and within the scope of the invention are presented below:

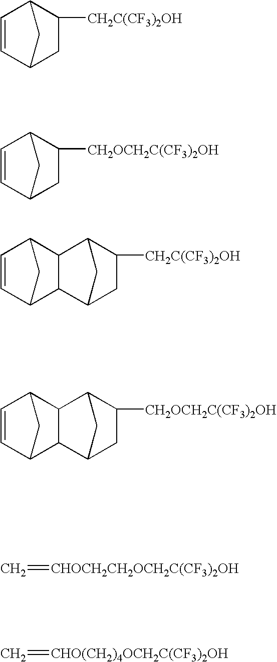

As is well known to those skilled in the polymer art, an ethylenically unsaturated compound undergoes free radical polymerization to afford a polymer having a repeat unit that is derived from the ethylenically unsaturated compound. Specifically, ethylenically unsaturated compound having structure: 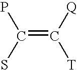
are described above with regard to copolymer (a1).

The fluoropolymer having at least one fluoroalcohol group (c) is selected from the group consisting of:
(c1) a fluorine-containing polymer comprising a repeat unit derived from at least one ethylenically unsaturated compound containing a fluoroalcohol functional group having the structure:
   —C(R_{f})(R_{f}′)OH
   wherein R_{f} and R_{f}′ are as described above;
(c2) a fluorine-containing copolymer comprising a repeat unit derived from at least one ethylenically unsaturated compound characterized in that at least one ethylenically unsaturated compound is cyclic or polycyclic, at least one ethylenically unsaturated compound contains at least one fluorine atom covalently attached to an ethylenically unsaturated carbon atom, and at least one ethylenically unsaturated compound is comprised of a fluoroalcohol functional group having the structure:
   —C(R_{f})(R_{f}′)OH
   wherein R_{f} and R_{f}′ are as described above;
(c3) a fluorine-containing copolymer comprising:
   (i) a repeat unit derived from at least one ethylenically unsaturated compound containing at least three fluorine atoms covalently attached to two ethylenically unsaturated carbon atoms; and
      (ii) a repeat unit derived from an ethylenically unsaturated compound comprised of a fluoroalcohol functional group having the structure:
         —C(R_{f})(R_{f}′)OH
         wherein R_{f} and R_{f}′ are as described above.
(c4) a fluorine-containing copolymer comprising a repeat unit derived from at least one ethylenically unsaturated compound containing a fluoroalcohol functional group having the structure:
   —ZCH₂C(R_{f})(R_{f}′)OH
   wherein R_{f} and R_{f}′ are as described above; and Z is an element selected from Group VA, and other Group VIA of the Periodic Table of the Elements (CAS Version). Typically X is a sulfur, oxygen, nitrogen or phosphorus atom;
(c5) a fluorine-containing polymer comprising the structure: 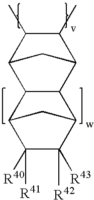
   wherein each of R⁴⁰, R⁴¹, R⁴², and R⁴³ independently is hydrogen atom, a halogen atom, a hydrocarbon group containing from 1 to 10 carbon atoms, a hydrocarbon group substituted with at least one O, S, N, P or halogen and having 1 to 12 carbons atoms, for example, an alkoxy group, a carboxylic acid group, a carboxylic ester group or a functional group containing the structure:
   —C(R_{f})(R_{f}′)OR⁴⁴
   wherein R_{f} and R_{f}′ are as describe above; R⁴⁴ is a hydrogen atom or an acid- or base-labile protecting group; v is the number of repeat units in the polymer; w is 0-4; at least one of the repeat units has a structure whereby at least one of R⁴⁰, R⁴¹, R⁴², and R⁴³ contains the structure C(R_{f})(R_{f}′)OR⁴⁴, for example, R⁴⁰, R⁴¹ and R⁴² are a hydrogen atom and R⁴³ is CH₂OCH₂C(CF₃)₂OCH₂CO₂C(CH₃)₃ wherein CH₂CO₂C(CH₃)₃ is an acid or base labile protecting group or R⁴³ is OCH₂C(CF₃)₂OCH₂CO₂C(CH₃)₃ wherein OCH₂CO₂C(CH₃)₃ is an acid or base labile protecting group; and
(c6) a polymer comprising:
   (i) a repeat unit derived from at least one ethylenically unsaturated compound containing a fluoroalcohol functional group having the structure:
      —C(R_{f})(R_{f}′)OH
      wherein R_{f} and R_{f}′ areas described above; and
   (ii) a repeat unit derived from at least one ethylenically unsaturated compound having the structure:
      (H)(R⁴⁵)C═C(R⁴⁶)(CN)
      wherein R⁴⁵ is a hydrogen atom or CN group; R⁴⁶ is C₁-C₈ alkyl group, hydrogen atom, or CO₂R⁴⁷ group, where R⁴⁷ is C₁-C₈ alkyl group or hydrogen atom.

The fluoropolymer or copolymer comprises a repeat unit (discussed infra) derived from at least one ethylenically unsaturated compound containing a fluoroalcohol functional group that can have fluoroalkyl groups present as part of the fluoroalcohol group and are described earlier with regard to copolymer (b). These fluoroalkyl groups are designated R_{f} and R_{f′} as described above.

As is well known to those skilled in the polymer art, an ethylenically unsaturated compound undergoes free radical polymerization to afford a polymer having a repeat unit that is derived from the ethylenically unsaturated compound. Specifically, an ethylenically unsaturated compound having structure: 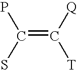
is described above with regard to copolymer (a1).

Each fluorine-containing copolymer according to this invention has an absorption coefficient of less than 4.0 μm⁻¹ at a wavelength of 157 nm, preferably of less than 3.5 μm⁻¹ at this wavelength, more preferably, of less than 3.0 μm⁻¹ at this wavelength, and, still more preferably, of less than 2.5 μm⁻¹ at this wavelength.

The fluorinated polymers, photoresists, and processes of this invention that include a fluoroalcohol functional group may have the structure:
—ZCH₂C(R_{f})(R_{f}′)OH
wherein R_{f} and R_{f}′ are as described above; Z is as described above.

Some illustrative, but nonlimiting, examples of representative comonomers containing a fluoroalcohol functional group and within the scope of the invention are presented below:

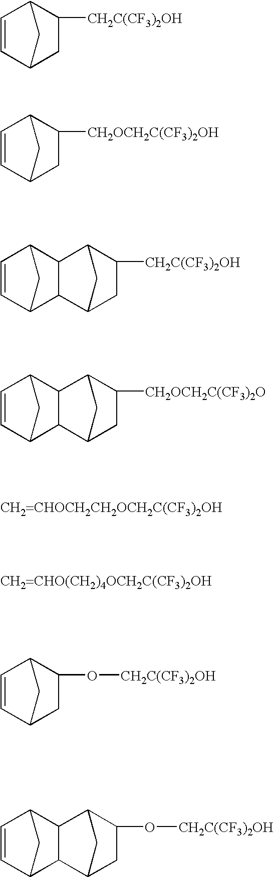

Various bifunctional compounds which can initially afford crosslinking and subsequently be cleaved (e.g., upon exposure to strong acid) are also useful as comonomers in the copolymers of this invention. As an illustrative, but non-limiting example, the bifunctional comonomer NB—F—OMOMO—F—NB is desirable as a comonomer in the copolymers of this invention. This and similar bifunctional comonomers, when present in the copolymer component(s) of photoresist compositions of this invention, can afford copolymers that are of higher molecular weight and are lightly crosslinked materials. Photoresist compositions, incorporating these copolymers comprised of bifunctional monomers, can have improved development and imaging characteristics, since, upon exposure (which photochemically generates strong acid as explained infra), there results cleavage of the bifunctional group and consequently a very significant drop in molecular weight, which factors can afford greatly improved development and imaging characteristics (e.g., improved contrast). These fluoroalcohol groups and their embodiments are described in more detail as above and in PCT/US00/11539 filed Apr. 28, 2000.

At least a portion of the nitrile functionality that is present in the nitrile/fluoroalcohol polymers results from incorporation of repeat unit(s) derived from at least one ethylenically unsaturated compound having at least one nitrile group and having the structure:
(H)(R⁴⁸)C═C(R⁴⁹)(CN)
wherein R⁴⁸ is a hydrogen atom or cyano group (CN); R⁴⁹ is an alkyl group ranging from 1 to about 8 carbon atoms, CO₂R⁵⁰ group wherein R⁵⁰ is an alkyl group ranging from 1 to about 8 carbon atoms, or hydrogen atom. Acrylonitrile, methacrylonitrile, fumaronitrile (trans-1,2-dicyanoethylene), and maleonitrile (cis-1,2-dicyanoethylene) are preferred. Acrylonitrile is most preferred.

The nitrile/fluoroalcohol polymers typically are characterized in having a repeat unit derived from at least one ethylenically unsaturated compound containing the fluoroalcohol functional group that is present in the nitrile/fluoroalcohol polymers from about 10 to about 60 mole % and a repeat unit derived from the at least one ethylenically unsaturated compound containing at least one nitrile group present in the polymer from about 20 to about 80 mole %. The nitrile/fluoroalcohol polymers more typically with respect to achieving low absorption coefficient values are characterized in having a repeat unit derived from at least one ethylenically unsaturated compound containing the fluoroalcohol functional group that is present in the polymers at less than or equal to 45 mole %, and, still more typically, at less than or equal to 30 mole % with relatively small amounts of a repeat unit containing the nitrile group making at least a portion of the balance of the polymer.

In one embodiment, the polymer includes at least one protected functional group. The functional group of the at least one protected functional group is, typically, selected from the group consisting of acidic functional groups and basic functional groups. Nonlimiting examples of functional groups of the protected functional group are carboxylic acids and fluoroalcohols.

In another embodiment, a nitrile/fluoroalcohol polymer can include aliphatic polycyclic functionality. In this embodiment, the percentage of repeat units of the nitrile/fluoroalcohol polymer containing aliphatic polycyclic functionality ranges from about 1 to about 70 mole %; preferably from about 10 to about 55 mole %; and more typically ranges from about 20 to about 45 mole %.

The nitrile/fluoroalcohol polymers can contain additional functional groups beyond those specifically mentioned and referenced herein with the proviso that, preferably, aromatic functionality is absent in the nitrile/fluoroalcohol polymers. The presence of aromatic functionality in these polymers has been found to detract from their transparency and result in their being too strongly absorbing in the deep and extreme UV regions to be suitable for use in layers that are imaged at these wavelengths.

In some embodiments, the polymer is a branched polymer comprising one or more branch segment(s) chemically linked along a linear backbone segment. The branched polymer can be formed during free radical addition polymerization of at least one ethylenically unsaturated macromer component and at least one ethylenically unsaturated comonomer. The branched polymer may be prepared by any conventional addition polymerization process. The branched polymer, or comb polymer, may be prepared from one or more compatible ethylenically unsaturated macromer components and one or more compatible, conventional ethylenically unsaturated macromer components and one or more compatible, conventional ethylenically unsaturated monomer component(s). Typically addition polymerizable, ethylenically unsaturated monomer components are acrylonitrile, methacrylonitrile, fumaronitrile, maleonitrile, protected and/or unprotected unsaturated fluoroalcohols, and protected and/or unprotected unsaturated carboxylic acids. The structure and process of making this type of branched polymers is discussed for polymer type (b) above, and as described in WO 00/25178.

The fluoropolymers with at least one fluoroalcohol may further comprise a spacer group selected from the group consisting of ethylene, alpha-olefins, 1,1′-disubstituted olefins, vinyl alcohols, vinyl ethers, and 1,3-dienes.

Polymer (d) comprises an amorphous vinyl homopolymer of perfluoro(2,2-dimethyl-1,3-dioxole) or CX₂═CY₂ where X═F or CF₃ and Y═—H or amorphous vinyl copolymer of perfluoro(2,2-dimethyl-1,3-dioxole) and CX₂═CY₂, said homopolymer or copolymer optionally containing one or more comonomer CR⁵¹R⁵²═CR⁵³R⁵⁴ where each of the R⁵¹, R⁵², R⁵³ is selected independently from H or F and where R⁵⁴ is selected from the group consisting of —F, —CF₃, —OR⁵⁵ where R⁵⁵ is CnF2n+1 with n=1 to 3, —OH (when R⁵³═H), and Cl (when R⁵¹, R⁵², and R⁵³═F). Polymer (d) may additionally comprise amorphous vinyl copolymers of CH₂═CHCF₃ and CF₂═CF₂ in 1:2 to 2:1 ratio, CH₂═CHF and CF₂═CFCl in 1:2 to 2:1 ratio, CH₂═CHF and CClH═CF₂ in 1:2 to 2:1 ratio, perfluoro(2-methylene-4-methyl-1,3-dioxolane) in any ratio with perfluoro(2,2-dimethyl-1,3-dioxole), perfluoro(2-methylene-4-methyl-1,3-dioxolane) in any ratio with vinylidene fluoride that is amorphous, and the homopolymer of perfluoro(2-methylene-4-methyl-1,3-dioxolane).

These polymers were made by polymerization methods known in the art for fluoropolymers. All of the polymers can be made by sealing the monomers, an inert fluid (such as CF₂ClCCl₂F, CF₃CFHCFHCF₂CF₃, or carbon dioxide), and a soluble free radical initiator such as HFPO dimer peroxide 1 or Perkadox® 16N in a chilled autoclave and then heating
CF₃CF₂CF₂OCF(CF₃)(C═O)OO(C═O)CF(CF₃)OCF₂CF₂CF₃ 1
as appropriate to initiate polymerization. For HFPO dimer peroxide 1 room temperature (˜25° C.) is a convenient polymerization temperature whereas for Perkadox® temperatures from 60 to 90° C. can be used. Depending upon the monomers and the polymerization temperature, pressures can vary from atmospheric pressure to 500 psi or higher. The polymer can then be isolated by filtration when formed as an insoluble precipitate or by evaporation or precipitation when soluble in the reaction mixture. In many instances the apparently dry polymer still retains considerable solvent and/or unreacted monomer and must be dried further in a vacuum oven preferably under nitrogen bleed. Many of the polymers can also be made by aqueous emulsion polymerization effected by sealing deionized water, an initiator such as ammonium persulfate or Vazo® 56 WSP, monomers, a surfactant such as ammonium perfluorooctanoate or a dispersant such as methyl cellulose in a chilled autoclave and heating to initiate polymerization. The polymer can be isolated by breaking any emulsion formed, filtering, and drying. In all instances oxygen should be excluded from the reaction mixture. Chain transfer agents such as chloroform may be added to lower molecular weight.

A nitrile/fluoroalcohol-containing polymer prepared from the substituted or unsubstituted vinyl ethers (e) comprise:
(e1) a polymer comprising:
   (i) a repeat unit derived from at least one ethylenically unsaturated compound comprising a vinyl ether functional group and having the structure:
      CH₂═CHO—R⁵⁶
      where R⁵⁶ is an alkyl group having 1 to 12 carbon atoms, aryl, aralkyl, or alkaryl group having from 6 to about 20 carbon atoms, or said groups substituted with at least one S, O, N or P atom; and
   (ii) a repeat unit derived from at least one ethylenically unsaturated compound having the structure:
      (H)(R⁵⁷)C═C(R⁵⁸)(CN)
wherein R⁵⁷ is a hydrogen atom or cyano group; R⁵⁸ is an alkyl group ranging from 1 to about 8 carbon atoms, CO₂R⁵⁹ group wherein R⁵⁹ is an alkyl group ranging from 1 to about 8 carbon atoms, or hydrogen atom; and
   (iii) a repeat unit derived from at least one ethylenically unsaturated compound comprising an acidic group; and
(e2) a polymer comprising:
   (i) a repeat unit derived from at least one ethylenically unsaturated compound comprising a vinyl ether functional group and a fluoroalcohol functional group and having the structure:
      C(R⁶⁰)(R⁶¹)═C(R⁶²)—O-D-C(R_{f})(R_{f}′)OH
      wherein R⁶⁰, R⁶¹, and R⁶² independently are hydrogen atom, alkyl group ranging from 1 to about 3 carbon atoms, D is at least one atom that links the vinyl ether functional group through an oxygen atom to a carbon atom of the fluoroalcohol functional group; R_{f} and R_{f}′ are as described above; and
   (ii) a repeat unit derived from at least one ethylenically unsaturated compound having the structure:
      (H)(R⁵⁷)C═C(R⁵⁸)(CN)
      wherein R⁵⁷ is a hydrogen atom or cyano group; R⁵⁸ is an alkyl group ranging from 1 to about 8 carbon atoms, CO₂R⁵⁹ group wherein R⁵⁹ is an alkyl group ranging from 1 to about 8 carbon atoms, or hydrogen atom; and
(iii) a repeat unit derived from at least one ethylenically unsaturated compound comprising an acidic group.

The fluoroalcohol groups and embodiments are described in more detail for polymers (c6) above. Some illustrative, but nonlimiting, examples of vinyl ether monomers falling within the generalized structural formula (given supra) containing a fluoroalcohol functional group and within the scope of the invention are presented below:
CH₂═CHOCH₂CH₂OCH₂C(CF₃)₂OH CH₂═CHO(CH₂)₄OCH₂C(CF₃)₂OH
The nitrile groups and their embodiments, and linear and branched polymers made with nitrile and fluoroalcohol groups and their embodiments, are also described and referenced in more detail for polymers (c6) above.

These polymers may be present in the amount of about 10 to about 99.5% by weight, based on the weight of the total composition (solids).

Photoactive Component (PAC)

If the polymers in the polymer blend are not photoactive, the compositions of this invention may contain a photoactive component (PAC) that is not chemically bonded to the fluorine-containing polymer, i.e. the photoactive component is a separate component in the composition. The photoactive component usually is a compound that produces either acid or base upon exposure to actinic radiation. If an acid is produced upon exposure to actinic radiation, the PAC is termed a photoacid generator (PAG). If a base is produced upon exposure to actinic radiation, the PAC is termed a photobase generator (PBG).

Suitable photoacid generators for this invention include, but are not limited to, 1) sulfonium salts (structure I), 2) iodonium salts (structure II), and 3) hydroxamic acid esters, such as structure III.

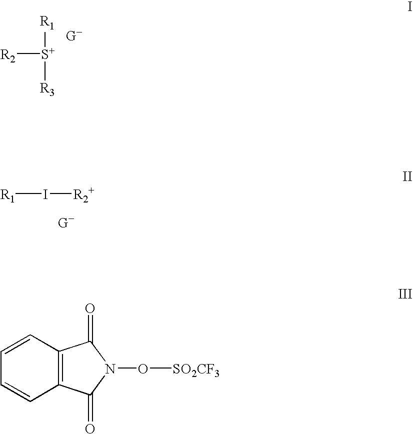

In structures I-II, R₁-R₃ are independently substituted or unsubstituted aryl or substituted or unsubstituted C₁-C₂₀ alkylaryl (aralkyl). Representative aryl groups include, but are not limited to, phenyl and naphthyl. Suitable substituents include, but are not limited to, hydroxyl (—OH) and C₁-C₂₀ alkyloxy (e.g., C₁₀H₂₁O. The anion G⁻ in structures I-II can be, but is not limited to, SbF₆— (hexafluoroantimonate), CF₃SO₃— (trifluoromethylsulfonate=triflate), and C₄F₉SO₃— (perfluorobutylsulfonate).

Bases/Surfactants:

Bases and surfactants of this invention are useful to improve imaging properties. Some useful bases include tributylamine, tripentylamine, trihexylamine, triheptylamine, trioctylamine, benzimidazole, 4-phenylpyridine, 4,4′-diaminodiphenyl ether, nicotinamide, 1-piperidinoethanol, triethanolamine, 3-piperidino-1,2-propanediol, 2,2,6,6-tetramethylpiperidinol, tetrabutylammonium hydroxide, tetrabutylammonium acetate, and tetrabutylammonium lactate. Some useful surfactants include perfluorooctanoic acid ammonium salt, perfluorononanoic acid ammonium salt, ZONYL® ) (Trade name of DuPont) FSA, FSN, FSO, and FSK fluorosurfactants, polyoxyethylene stearylether, polyoxyethylene oleyl ether, polyoxyethylene octylphenyl ether, polyoxyethylene nonylphenyl ether, polyethylene glycol dilaurate, polyethylene glycol distearate, alkylbenzene sulphonates, sodium sulfosuccinate, and sodium lauryl sulfate.

Bases and surfactants may be present in the amount of about 0.001 to about 5.0%, typically about 0.01 to about 2.0%, based on the weight of the total composition.

Dissolution Inhibitor

Various dissolution inhibitors can be utilized in this invention. Ideally, dissolution inhibitors (DIs) for the far and extreme UV resists (e.g., 193 nm resists) are designed/chosen to satisfy multiple materials needs including dissolution inhibition, plasma etch resistance, and adhesion behavior of resist compositions comprising a given DI additive. Some dissolution inhibiting compounds also serve as plasticizers in resist compositions.

A variety of bile-salt esters (i.e., cholate esters) are particularly useful as DIs in the compositions of this invention. Bile-salt esters are known to be effective dissolution inhibitors for deep UV resists, beginning with work by Reichmanis et al. in 1983. (E. Reichmanis et al., “The Effect of Substituents on the Photosensitivity of 2-Nitrobenzyl Ester Deep UV Resists”, J. Electrochem. Soc. 1983, 130, 1433-1437.) Bile-salt esters are particularly attractive choices as DIs for several reasons, including their availability from natural sources, their possessing a high alicyclic carbon content, and particularly for their being transparent in the Deep and vacuum UV region of the electromagnetic spectrum (e.g., typically they are highly transparent at 193 nm). Furthermore, the bile-salt esters are also attractive DI choices since they may be designed to have widely ranging hydrophobic to hydrophilic compatibilities depending upon hydroxyl substitution and functionalization.

Representative bile-acids and bile-acid derivatives that are suitable as additives and/or dissolution inhibitors for this invention include, but are not limited to, those illustrated below, which are as follows: cholic acid (IV), deoxycholic acid (V), lithocholic acid (VI), t-butyl deoxycholate (VII), t-butyl lithocholate (VIII), and t-butyl-3-α-acetyl lithocholate (IX). Bile-acid esters, including compounds VII-IX, are preferred dissolution inhibitors in this invention.

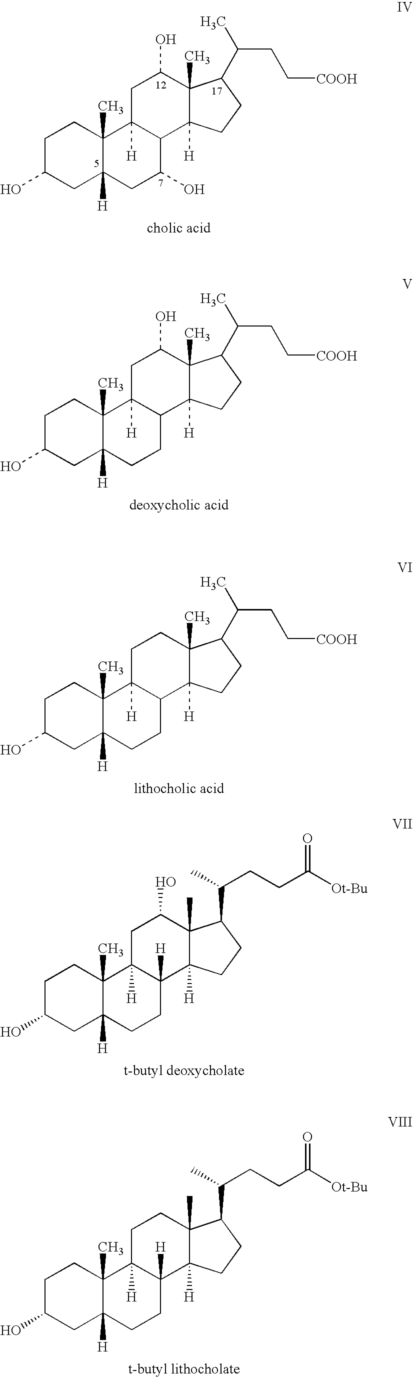

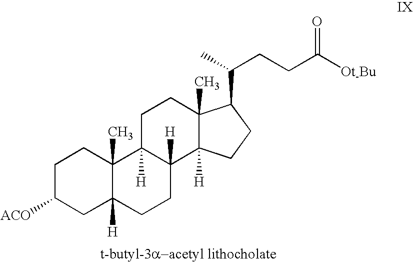

The amount of dissolution inhibitor can vary depending upon the choice of polymer. When the polymer lacks sufficient protected acid group for suitable image forming a dissolution inhibitor can be used to enhance the image forming properties of the photoresist composition.

Other Components

The compositions of this invention can contain optional additional components. Examples of additional components which can be added include, but are not limited to, resolution enhancers, adhesion promoters, residue reducers, coating aids, plasticizers, and T_{g} (glass transition temperature) modifiers. Crosslinking agents may also be present in negative-working resist compositions. Some typical crosslinking agents include bis-azides, such as, 4,4′-diazidodiphenyl sulfide and 3,3′-diazidodiphenyl sulfone. Typically, a negative working composition containing at least one crosslinking agent also contains suitable functionality (e.g., unsaturated C═C bonds) that can react with the reactive species (e.g., nitrenes) that are generated upon exposure to UV to produce crosslinked polymers that are not soluble, dispersed, or substantially swollen in developer solution.

Process for Forming a Photoresist Image

The process for preparing a photoresist image on a substrate comprises, in order:
(X) imagewise exposing the photoresist layer to form imaged and non-imaged areas, wherein the photoresist layer is prepared from a photoresist composition comprising:
   (A) a polymers selected from the group consisting of (a) to (e); and mixtures thereof;
   (B) a photoactive compound;
   (C) a functional compound selected from the group consisting of a base and a surfactant; and
(Y) developing the exposed photoresist layer having imaged and non-imaged areas to form the relief image on the substrate.
   Imagewise Exposure

The photoresist layer is prepared by applying a photoresist composition onto a substrate and drying to remove the solvent. The so formed photoresist layer is sensitive in the ultraviolet region of the electromagnetic spectrum and especially to those wavelengths≦365 nm. Imagewise exposure of the resist compositions of this invention can be done at many different UV wavelengths including, but not limited to, 365 nm, 248 nm, 193 nm, 157 nm, and lower wavelengths. Imagewise exposure is preferably done with ultraviolet light of 248 nm, 193 nm, 157 nm, or lower wavelengths, preferably it is done with ultraviolet light of 193 nm, 157 nm, or lower wavelengths, and most preferably, it is done with ultraviolet light of 157 nm or lower wavelengths. Imagewise exposure can either be done digitally with a laser or equivalent device or non-digitally with use of a photomask. Digital imaging with a laser is preferred. Suitable laser devices for digital imaging of the compositions of this invention include, but are not limited to, an argon-fluorine excimer laser with UV output at 193 nm, a krypton-fluorine excimer laser with UV output at 248 nm, and a fluorine (F₂) laser with output at 157 nm. Since, as discussed supra, use of UV light of lower wavelength for imagewise exposure corresponds to higher resolution (lower resolution limit), the use of a lower wavelength (e.g., 193 nm or 157 m or lower) is generally preferred over use of a higher wavelength (e.g., 248 nm or higher).

Development

The components in the resist compositions of this invention must contain sufficient functionality for development following imagewise exposure to UV light. Preferably, the functionality is acid or protected acid such that aqueous development is possible using a basic developer such as sodium hydroxide solution, potassium hydroxide solution, or ammonium hydroxide solution.

For example, polymers (c) in the resist compositions of this invention are typically acid-containing materials comprised of at least one fluoroalcohol-containing monomer of structural unit:
—C(R_{f})(R_{f}′)OH
wherein R_{f} and R_{f}′ are as described above. The level of acidic fluoroalcohol groups is determined for a given composition by optimizing the amount needed for good development in aqueous alkaline developer.

When an aqueous processable photoresist is coated or otherwise applied to a substrate and imagewise exposed to UV light, development of the photoresist composition may require that the binder material should contain sufficient acid groups (e.g., fluoroalcohol groups) and/or protected acid groups that are at least partially deprotected upon exposure to render the photoresist (or other photoimageable coating composition) processable in aqueous alkaline developer. In case of a positive-working photoresist layer, the photoresist layer will be removed during development in portions which are exposed to UV radiation but will be substantially unaffected in unexposed portions during development by aqueous alkaline liquids such as wholly aqueous solutions containing 0.262 N tetramethylammonium hydroxide (with development at 25° C. usually for less than or equal to 120 seconds). In case of a negative-working photoresist layer, the photoresist layer will be removed during development in portions which are unexposed to UV radiation but will be substantially unaffected in exposed portions during development using either a critical fluid or an organic solvent.

A critical fluid, as used herein, is one or more substances heated to a temperature near or above its critical temperature and compressed to a pressure near or above its critical pressure. Critical fluids in this invention are at least at a temperature that is higher than 15° C. below the critical temperature of the fluid and are at least at a pressure higher than 5 atmosphers below the critical pressure of the fluid. Carbon dioxide may be used for the critical fluid in the present invention. Various organic solvents can also be used as developer in this invention. These include, but are not limited to, halogenated solvents and non-halogenated solvents. Halogenated solvents are typical and fluorinated solvents are more typical.

Substrate

The substrate employed in this invention can illustratively be silicon, silicon oxide, silicon nitride, or various other materials used in semiconductive manufacture.

### EXAMPLES

Glossary

Analytical/Measurements

| | |
|---|---|
| bs | broad singlet |
| δ | NMR chemical shift measured in the |
| | indicated solvent |
| g | gram |
| NMR | Nuclear Magnetic Resonance |
| ¹HNMR | Proton NMR |
| ¹³CNMR | Carbon-13 NMR |
| ¹⁹FNMR | Fluorine-19 NMR |
| s | singlet |
| sec. | second(s) |
| m | multiplet |
| mL | milliliter(s) |
| mm | millimeter(s) |
| T_{g} | Glass Transition Temperature |
| Mₙ | Number-average molecular weight of a |
| | given polymer |
| M_{w} | Weight-average molecular weight of a |
| | given polymer |
| P = M_{w}/Mₙ | Polydispersity of a given polymer |
| Absorption | AC = A/b, where A, absorbance, |
| coefficient | = Log ₁₀(1/T) and b = film thickness in |
| | microns, where T = transmittance as |
| | defined below. |
| Transmittance | Transmittance, T, = ratio of the radiant |
| | power transmitted by a sample to the |
| | radiant power incident on the sample and |
| | is measured for a specified wavelength |
| | (e.g., nm). |

Chemicals/Monomers

| | |
|---|---|
| AA | Acrylic acid |
| | Aldrich Chemical Co., Milwaukee, WI |
| AIBN | 2,2′-azobisisobutyronitrile |
| | Aldrich Chemical Co., Milwaukee, WI |
| CFC-113 | 1,1,2-Trichlorotrifluoroethane |
| | (E. I. du Pont de Nemours and Company, |
| | Wilmington, DE) |
| HFIBO | Hexafluoroisobutylene epoxide |
| MEK | 2-Butanone |
| | Aldrich Chemical Co., Milwaukee, WI |
| NB | Norbornene = Bicyclo[2.2.1]hept-2-ene |
| | Aldrich Chemical Co., Milwaukee, WI |
| Perkadox ® 16 N | Di-(4-tert-butylcyclohexyl)peroxydicarbonate |
| | Noury Chemical Corp., Burt, NY |
| PGMEA | Propylene glycol methyl ether acetate |
| | Aldrich Chemical Co., Milwaukee, WI |
| tBA | Tertiary-Butyl acrylate |
| TCB | Trichlorobenzene |
| | Aldrich Chemical Co., Milwaukee, WI |
| TFE | Tetrafluoroethylene |
| | (E. I. du Pont de Nemours and Company, |
| | Wilmington, DE) |
| THF | Tetrahydrofuran |
| | Aldrich Chemical Co., Milwaukee, WI |
| Vazo ® 52 | 2,4-Dimethyl-2,2′-azobis(pentanenitrile) |
| | (E. I. du Pont de Nemours and Company, |
| | Wilmington, DE) |
| NB—F—O—t-BuAc | 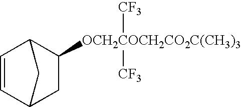 |
| NB—F—O—t-BuAc | 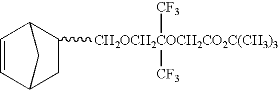 |

| | | |
|---|---|---|
| NB-Me-OH NB-Me-F-OH NB-Me-F-OMOM | X═OH X═OCH₂C(CF₃)₂O X═OCH₂C(CF₃₎₂OCH₂OCH₃ | 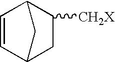 |
| NB-OAc NB-OH NB-F-OH NB-F-OMOM | X═OCOCH_{3 X═OH X═OCH}₂C(CF₃)₂OH X═OCH₂C(CF₃)₂OCH₂OCH₃ | 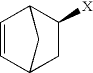 |

| | |
|---|---|
| VE-F-OH | CH₂═CHOCH₂CH₂OCH₂C(CF₃)₂OH |
| VE-F-OMOM | CH₂═CHOCH₂CH₂OCH₂C(CF₃)₂OCH₂OCH₃ |

Ultraviolet

| | |
|---|---|
| Extreme UV | Region of the electromagnetic spectrum in |
| | the ultraviolet that ranges from |
| | 10 nanometers to 200 nanometers |
| Far UV | Region of the electromagnetic spectrum in |
| | the ultraviolet that ranges from |
| | 200 nanometers to 300 nanometers |
| UV | Ultraviolet region of the electromagnetic |
| | spectrum which ranges from 10 nanometers |
| | to 390 nanometers |
| Near UV | Region of the electromagnetic spectrum in |
| | the ultraviolet that ranges from 300 |
| | nanometers to 390 nanometers |

### Example 1

Synthesis of a TFE/NB—F—OH/tBA Terpolymer

Synthesis of NB—F—OH was as follows:

A dry round bottom flask equipped with mechanical stirrer, addition funnel and nitrogen inlet was swept with nitrogen and charged with 19.7 g (0.78 mol) of 95% sodium hydride and 500 mL of anhydrous DMF. The stirred mixture was cooled to 5° C. and 80.1 g (0.728 mol) of exo-5-norbornen-2-ol was added dropwise so that the temperature remained below 15° C. The resulting mixture was stirred for ½ hr. HFIBO (131 g, 0.728 mol) was added dropwise at room temperature. The resulting mixture was stirred overnight at room temperature. Methanol (40 mL) was added and most of the DMF was removed on a rotary evaporator under reduced pressure. The residue was treated with 200 mL water and glacial acetic acid was added until the pH was about 8.0. The aqueous mixture was extracted with 3×150 mL ether. The combined ether extracts were washed with 3×150 mL water and 150 mL brine, dried over anhydrous sodium sulfate and concentrated on a rotary evaporator to an oil. Kugelrohr distillation at 0.15-0.20 torr and a pot temperature of 30-60° C. gave 190.1 (90%) of product. ¹H NMR (δCD₂Cl₂) 1.10-1.30 (m, 1H), 1.50 (d, 1H), 1.55-1.65 (m, 1H), 1.70 (s, 1H), 1.75 (d, 1H), 2.70 (s, 1H), 2.85 (s, 1H), 3.90 (d, 1H), 5.95 (s, 1H), 6.25 (s, 1H). Another sample prepared in the same fashion was submitted for elemental analysis. Calcd. for C₁₁H₁₂F₆O₂: C, 45.53; H, 4.17; F, 39.28. Found: C, 44.98; H, 4.22; F, 38.25. The synthesis of NB—F—OH is described in PCT Int. Appl. WO 2000067072, published Nov. 9, 2000).

A 200 mL stainless steel autoclave was charged with 48.7 g (0.168 mol) of NB—F—OH, made as described above, 1.54 g (0.012 mol) of tert-butylacrylate (tBA, Aldrich Chemical Company), 75 mL of 1,1,2-trichlorotrifluoroethane and 0.6 g of Perkadox® 16. The vessel was closed, cooled, evacuated and purged with nitrogen several times. It was then charged with 42 g (0.42 mol) of tetrafluoroethylene (TFE). The autoclave was agitated with the vessel contents at 50° C. for about 18 hr resulting in a pressure change from 294 psi to 271 psi. The vessel was cooled to room temperature and vented to one atmosphere. The vessel contents were removed using 1,1,2-trichlorotrifluoroethane to rinse giving a clear solution. This solution was added slowly to excess hexane resulting in precipitation of a white polymer which was dried over night in a vacuum oven. Yield was 11.3 g (12%). GPC analysis: Mn=7300; Mw=10300; Mw/Mn=1.41. DSC analysis: A Tg of 135° C. was observed on second heat. The fluorine NMR spectrum showed peaks at −75.6 ppm (CF₃) and −95 to −125 ppm (CF₂) confirming incorporation of NB—F—OH and TFE, respectively. The polymer was analyzed by carbon NMR and was found to contain 39 mole % TFE, 42 mole % NB—F—OH and 18 mole % tBA by integration of the appropriate peaks.

Analysis found: C, 43.75; H, 3.92; F, 40.45.

### Example 2

Terpolymer of TFE, NB—F—OH and tert-Butyl Acrylate was prepared using the following procedure:

A metal pressure vessel of approximate 270 mL capacity was charged with 71.05 g NB—F—OH, 0.64 g tert-butyl acrylate and 25 mL 1,1,2-trichlorotrifluoroethane. The vessel was closed, cooled to about−15° C. and pressured to 400 psi with nitrogen and vented several times. The reactor was heated to 50° C. and TFE was added until the internal pressure reached 340 psi. A solution of 75.5 g of NB—F—OH and 9.39 g of tert-butyl acrylate diluted to 100 mL with 1,1,2-trichlorotrifluoroethane was pumped into the reactor at a rate of 0.10 mL/min for 12 hr. Simultaneously with the start of the monomer feed solution, a solution of 6.3 g Perkadox®16N and 30-35 mL methyl acetate diluted to 75 mL with 1,1,2-trifluorotrichloroethane was pumped into the reactor at a rate of 2.0 mL/minute for 6 minutes, and then at a rate of 0.08 mL/minute for 8 hours. The internal pressure was maintained at 340 psi by addition of TFE as required. After a 16 hours reaction time, the vessel was cooled to room temperature and vented to 1 atmosphere. The recovered polymer solution was added slowly to an excess of hexane while stirring. The precipitate was filtered, washed with hexane and dried in a vacuum oven. The resulting solid was dissolved in a mixture of THF and 1,1,2-trichlorotrifluoroethane and added slowly to excess to hexane. The precipitate was filtered, washed with hexane and dried in a vacuum oven overnight to give 47.5 g of white polymer. From its ¹³C NMR spectrum, the polymer composition was found to be 35% TFE, 42% NB—F—OH and 22% tBA. DSC: Tg=151° C. GPC: Mn=6200; Mw=9300; Mw/Mn=1.50. Anal. Found: C, 44.71; H, 4.01; F, 39.38.

### Example 3

The homopolymer of NB-Me-F—OH was prepared using the following procedure:

Under nitrogen, 0.19 g (0.49 mmol) of the allyl palladium complex [(η³-MeCHCHCH₂)PdCl]₂ and 0.34 g (0.98 mmol) silver hexafluoroantimonate were suspended in chlorobenzene (40 mL). The resulting mixture was stirred at room temperature for 30 minutes. It was then filtered to remove precipitated AgCl, and an additional 10 mL chlorobenzene added. The resulting solution was added to 15.0 g (49.0 mmol) of NB-Me-F—OH. The resulting reaction mixture was stirred for three days at room temperature. The crude product polymer was isolated by precipitation in hexane. This material was taken up in acetone to give a 10 weight % solution, and filtered through a 0.2 μm Teflon® filter; the acetone filtrate was then concentrated to dryness, affording 7.8 g of addition copolymer. GPC: Mₙ=6387; M_{w}=9104; M_{w}/Mₙ=1.43. Anal. Found: C, 46.28; H, 4.81; F, 34.22. ¹H NMR (CD₂Cl₂) of the polymer was consistent with the saturated vinyl-addition polymer shown below:

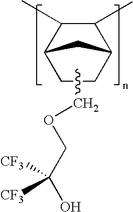

### Example 4

NB—F—OH/NB—F—O-t-BuAc Copolymer was synthesized by Polymer Modification using the following procedure:

A 500 mL round bottom flask with mechanical stirrer, addition funnel and reflux condenser was charged with 53.6 g of a NB—F—OH vinyl addition homopolymer which was calculated to contain 0.185 mol of hexafluoroisopropanol groups, 200 mL of acetonitrile and 30.6 g (0.222 mol) of potassium carbonate. This mixture was refluxed for 0.5 hr. tert-Butyl bromoacetate (10.8 g, 0.055 mol) was added dropwise and the resulting mixture was refluxed for 3 hr. The mixture was cooled to room temperature and diluted by addition of 300 mL acetone. The mixture was then filtered and concentrated under vacuum to a volume of approximately 200 mL. The concentrated mixture was slowly poured into 5.4 L 1.0% aqueous HCl. The resulting precipitate was filtered and washed with water. The precipitate was then dissolved in 200 mL acetone; to this solution was added a solution of 5 mL water and 3 mL 36% aqueous HCl. The resulting solution was slightly cloudy. It was poured into 5.4 L of water. The precipitate was washed with water several times and dried to afford 44.0 g of NB—F—OH/NB—F—O-t-BuAc copolymer. ¹⁹F NMR (∂ acetone-d₆)-β73.1 (s, assigned to units from the NB—F—O-t-BuAc), −75.4 (s, assigned to units from NB—F—OH) By integration of the spectrum, the composition of the polymer was found to 64% NB—F—OH and 36% NB—F—O-t-BuAc. Samples of the polymer were spin coated from a 5% solution in 2-heptanone. The absorption coefficient at 157 nm was determined to be 3.15 μm⁻¹ at a film thickness of 47.2 nm and 2.70 μm⁻¹ at a film thickness of 45.7 nm.

### Example 5

NB-Me-F—OH/NB-Me-F—O-t-BuAc Copolymer was synthesized by Polymer Modification using the following procedure:

Example 4 was repeated with the following exception: a NB-Me-F—OH vinyl addition homopolymer was used instead of NB—F—OH vinyl addition homopolymer, to synthesize a NB-Me-F—OH/NB-Me-F—O-t-BuAc copolymer. ¹⁹F NMR (∂, acetone-d₆)-73.2 (s, assigned to units from the NB-Me-F—O-t-BuAc), −75.3 (s, assigned to units from NB-Me-F—OH). By integration of the spectrum, the composition of the polymer was found to 68% NB-Me-F—OH and 32% NB-Me-F—O-t-BuAc.

### Example 6

The following solution was prepared and magnetically stirred overnight.

| Component | Wt. (gm) |
|---|---|
| TFE/NB—F—OH/tBA copolymer | 0.520 |
| (weight ratio: feed, 70/28/2; | |
| analysis by ¹³C NMR, 39/42/18) | |
| as described in Example 1 | |
| 2-Heptanone solution of perfluorooctaonic acid, | 5.121 |
| ammonium salt (0.011 wt. %) | |
| t-Butyl Lithocholate | 0.060 |
| 6.82% (wt) solution of triphenylsulfonium nonaflate | 0.299 |
| dissolved in cyclohexanone which had been | |
| filtered through a 0.45 μ PTFE syringe filter. | |

Spin coating was done using a Brewer Science Inc. Model-100CB combination spin coater/hotplate on a 4 in. diameter Type “P”, <100> orientation, silicon wafer, development was performed on a Litho Tech Japan Co. Resist Development Analyzer (Model-790).

The wafer was prepared by depositing 6 mL of hexamethyldisilazane (HMDS) primer and spinning at 5000 rpm for 10 seconds. Then about 3 mL of the above solution, after filtering through a 0.45 μm PTFE syringe filter, was deposited and spun at 3000 rpm for 60 seconds and baked at 120° C. for 60 seconds.

248 nm imaging was accomplished by exposing the coated wafer to light obtained by passing broadband UV light from an ORIEL Model-82421 Solar Simulator (1000 watt) through a 248 nm interference filter which passes about 30% of the energy at 248 nm. Exposure time was 30 seconds, providing an unattenuated dose of 20.5 mJ/cm2. By using a mask with 18 positions of varying neutral optical density, a wide variety of exposure doses were generated. After exposure the exposed wafer was baked at 120° C. for 120 seconds.

The wafer was developed in aqueous tetramethylammonium hydroxide (TMAH) solution (ONKA NMD-3, 2.38% TMAH solution) for 60 seconds to generate a positive image.

### Example 7

The following solution was prepared and magnetically stirred:

| Component | Wt. (gm) |
|---|---|
| TFE/NB—F—OH/tBA copolymer | 5.506 |
| (35/42/22, as analyzed by ¹³C NMR), | |
| prepared in a manner similar to that | |
| as described in Example 2 | |
| 2-Heptanone | 48.652 |
| 6.82% (wt) solution of triphenylsulfonium nonaflate | 2.842 |
| dissolved in 2-heptanone which had been | |
| filtered through a 0.45μ PTFE syringe filter. | |

To ten 5.0 gm samples of the above solution were added 0.107 gm of a 0.0232 M solution of one of each of the following bases dissolved in 2-heptanone, available from Aldrich Chemical Co., Milwaukee, Wis., and stirred overnight:

A. Trioctylamine
B. Triethanolamine
C. 1-Piperidineethanol
D. 3-Piperidino-1,2-propanediol
E. 1-Piperidinepropionitrile
F. 2,2,6,6-Tetramethylpiperidine
G. 2,2,6,6-Tetramethyl-4-piperidinol
H. 1-Propyl-4-piperidone
I. Tetrabutylammonium Lactate*
J. Tetrabutylammoinum Hydroxide
*Prepared by adding tetrabutylammonium hydroxide to ethyl lactate

The resulting samples were spin coated onto a substrate. Spin coating was done using a Brewer Science Inc. Model-100CB combination spin coater/hotplate on a 4 in. diameter Type “P”, <100> orientation, silicon wafer. Development was performed on a Litho Tech Japan Co. Resist Development Analyzer (Model-790).

The wafer was prepared by depositing 6 mL of hexamethyldisilazane (HMDS) primer and spinning at 1000 rpm for 5 sec. and then 3500 rpm for 10 sec. Then 1-3 mL of the above solution, after filtering through a 0.2 μm PTFE syringe filter, was deposited and spun at 1800 rpm for 60 seconds and baked at 120° C. for 60 seconds.

248 nm imaging was accomplished by exposing the coated wafer to light obtained by passing broadband UV light from an ORIEL Model-82421 Solar Simulator (1000 watt) through a 248 nm interference filter which passes about 30% of the energy at 248 nm. Exposure time was 10 seconds, providing an unattenuated dose of 13.5 mJ/cm². By using a mask with 18 positions of varying neutral optical density, a wide variety of exposure doses were generated. After exposure the exposed wafer was baked at 100° C. for 60 seconds.

The wafer was developed in aqueous tetramethylammonium hydroxide (TMAH) solution (Shipley LDD-26W developer, 0.26N TMAH solution) for 10 sec. This test generated positive images, with the following clearing doses (mJ/cm²) required for the formulations with the above bases:

A. 3.9 mJ/cm²
B. 3.2 mJ/cm²
C. 2.4 mJ/cm²
D. 3.2 mJ/cm²
E. 6.8 mJ/cm²
F. 3.9 mJ/cm²
G. 3.9 mJ/cm²
H. 2.4 mJ/cm²
I. 5.3 mJ/cm²
J. 2.4 mJ/cm²

A formulation containing a terpolymer similar to that described in this example and base I. described above was exposed, developed and tested in a similar fashion to that described in Example 9 and showed an improvement in resolution.

### Example 8

Example 7 was repeated with the following exceptions: The following solution was prepared and magnetically stirred:

| Component | Wt. (gm) |
|---|---|
| NB—Me—F—OH/NB—Me—F—O—Ac-tBu copolymer | 6.607 |
| (68/32, as analyzed by ¹⁹F NMR) similar to that | |
| described in Example 5 | |
| 2-Heptanone | 46.983 |
| 6.82% (wt) solution of triphenylsulfonium nonaflate | 3.410 |
| dissolved in 2-heptanone which had been | |
| filtered through a 0.45μ PTFE syringe filter. | |

To ten 5.0 gm samples of the above solution were added 0.128 gm of a 0.0232 M solution of one of each of the bases disclosed in Example 7 dissolved in 2-heptanone, and stirred overnight.

Wafers were coated and prepared as described in Example 7 except that exposure time was 3 seconds instead of 10 seconds, providing an unattenuated dose of 4.0 mJ/cm².

This test generated positive images, with the following clearing doses (mJ/cm²) required for the formulations with the above bases:

A. 2.4 mJ/cm²
B. 1.2 mJ/cm²
C. 1.0 mJ/cm²
D. 1.2 mJ/cm²
E. 2.1 mJ/cm²
F. 2.1 mJ/cm²
G. 1.2 mJ/cm²
H. 1.2 mJ/cm²
I. 2.4 mJ/cm²
J. 2.4 mJ/cm²

### Example A

The following solution was prepared, magnetically stirred overnight, and filtered through a 0.45μ PTFE syringe filter before use:

| Component | Wt. (gm) |
|---|---|
| NB—Me—F—OH/NB—Me—F—O-tBuAc | 1.739 |
| (68/32) copolymer prepared | |
| similarly to that in Example 5 | |
| 2-Heptanone | 12.364 |
| 6.82% (wt) solution of triphenylsulfonium | 0.897 |
| nonaflate dissolved in cyclohexanone | |
| which had been filtered through a | |
| 0.45μ PTFE syringe filter. | |

This resist formulation was spin cast on an 8 inch Si wafer at a speed of 2000 rpm, yielding a film of measured thickness 2169 Å after PAB at 120° C. for 60 sec.

All imaging and open frame exposures were made using an Exitech 157 nm microstepper. Resist formulations were spin-coated on 8 inch Si wafers which were first vapor primed at 90° C. with hexamethyldisilazane (HMDS). The resulting films were soft baked, or post-apply baked (PAB), at 120° C. for 60 sec, and then their thicknesses were measured using a Prometrix interferometer which utilized Cauchy coefficients determined by variable angle spectroscopic ellipsometry measurements using a J.A. Woollam VU301 variable angle spectroscopic ellipsometer. After open frame exposure on the Exitech stepper (typically 100 exposure doses were made), or imaging using either a binary mask with numerical aperture (N.A.)=0.6 and partial coherence (σ)=0.7, or a Levenson strong phase shift mask with N.A.=0.6 and σ=0.3, the wafer was post-exposure baked (PEB) at 100° C. for 60 sec followed by a 60 sec puddle develop with Shipley LDD-26W 2.38% tetramethyl ammonium hydroxide. The open frame exposed wafers were then subjected to thickness measurements on the Prometrix interferometer in order to determine the thickness loss versus exposure dose, and the imaged wafers were examined using a JEOL 7550 top-down and tilt scanning electron microscope (SEM), and in some cases cross-sections were made and examined using a Hitachi 4500 SEM.

At an exposure dose of 24 mJ/cm² the image was found to exhibit features at 140 nm resolution.

### Example 9B

The same polymer formulation was used, but with the addition of 38 microliters of 0.5 wt % tetrabutylammonium lactate (TBALac) base to 1 milliliter of the resist. This corresponds to a molar concentration of the base equal to 10% of the molar concentration of the PAG. This formulation was spin cast on an 8 inch Si wafer at 2000 rpm, yielding after PAB at 120° C. for 60 sec a film of thickness 2087 Å. This film was exposed and developed as described above. The resulting image was then examined in the JEOL 7550 SEM and was observed to exhibit features at least as small as 60 nm at an exposure dose of 52 mJ/cm². These features were also examined in cross-section using the Hitachi 4500 SEM, and 100 nm 1:2 lines and spaces were well resolved and exhibited good line profiles, as did 60 nm 1:5 lines and spaces. These results demonstrate that this vinyl addition polymer can image at sub-100 nm resolution, with film thcknesses exceeding 200 nm, when formulated with added base.

### Example 9C

Another test was made using half as much added TBALac base, and the quality of the imaging was shown to be intermediate between the results with no added base and 10 mol % PAG added base. 100 nm 1:5 lines and spaces could be resolved.

### Example 9D

Another test was made in which the same initial polymer formulation was used (resin and PAG in 2-heptanone), but 10 mol % PAG of added tetrabutylammonium hydroxide (TBAOH) was used instead of TBALac. The resulting images showed resolution of 100 nm 1:3 lines and spaces.

### Example 9E

Open-Frame Exposures (Measurements of Dose-to-Clear, E₀, and Resist Contrast):

The above formulation was prepared again at a somewhat larger scale. This resist formulation was spin cast on an 8 inch Si wafer at a speed of 2000 rpm, yielding a film of measured thickness 2169 Å after PAB at 120° C. for 60 sec. This film was then exposed to 157 nm radiation in the Exitech stepper in a 10×10 open-frame pattern, with exposure dose varying from 0 to 10 mJ/cm² in increments of 0.1 mJ/cm². After exposure the film was PEB at 100° C. for 60 sec, followed by puddle development for 60 sec in Shipley LDD-26W. The resulting image was examined using a Prometrix interferometer in order to measure the film thickness remaining after development at the positions of all 100 exposure doses. The resulting data show that at an exposure dose of 7.4 mJ/cm² the film with 0% added base is completely removed by the developer (E₀=7.4 mJ/cm²).

### Example 9F

A second formulation was prepared by taking 4 milliliters of the same solution described above, and adding to that solution 154 microliters of a 0.5 wt % solution of TBALac in 2-heptanone. This yielded a resist formulation which had a base concentration equal to 10 mol % that of the PAG. This resist formulation was spin cast on an 8 inch Si wafer at a speed of 2000 rpm, yielding a film of measured thickness 2003 Å after PAB at 120° C. for 60 sec. This film was then exposed to 157 nm radiation in the Exitech stepper in a 10×10 open-frame pattern, with exposure dose varying from 0 to 30 mJ/cm² in increments of 0.3 mJ/cm². After exposure the film was PEB at 100° C. for 60 sec, followed by puddle development for 60 sec in Shipley LDD-26W. The resulting image was examined using a Prometrix interferometer in order to measure the film thickness remaining after development at the positions of all 100 exposure doses. The resulting data show that at an exposure dose of 25.8 mJ/cm² the film with 10% added base is completely removed by the developer (E₀=25.8 mJ/cm²).

### Example 9G

A third formulation was prepared by taking 3 milliliters of the same solution described above, and adding to that solution 90 microliters of a 0.5 wt % solution of TBAOH in 2-heptanone. This yielded a resist formulation which had a base concentration equal to 10 mol % that of the PAG. This resist formulation was spin cast on an 8 inch Si wafer at a speed of 2000 rpm, yielding a film of measured thickness 2001 Å after PAB at 120° C. for 60 sec. This film was then exposed to 157 nm radiation in the Exitech stepper in a 10×10 open-frame pattern, with exposure dose varying from 0 to 30 mJ/cm² in increments of 0.3 mJ/cm². After exposure the film was PEB at 100° C. for 60 sec, followed by puddle development for 60 sec in Shipley LDD-26W. The resulting image was examined using a Prometrix interferometer in order to measure the film thickness remaining after development at the positions of all 100 exposure doses. The resulting data show that at an exposure dose of 18.3 mJ/cm² the film with 10% added base is completely removed by the developer (E₀=18.3 mJ/cm²).

In all cases, with added base, the data show that the resists exhibit high contrast when exposed to 157 nm light. High contrast is one of the desirable features in a photoresist which can lead to high resolution imaging in semiconductor patterning, and these vinyl addition polymer resist formulations each have this desirable property.

1. A photoresist composition comprising:
(A) a nitrile/fluoroalcohol-containing polymer
(B) at least one photoactive component; and
(C) a functional compound selected from the group consisting of a base and a surfactant.

2. The composition of claim 1 wherein the functional compound is a base with a pKₐ of at least 5.

3. The photoresist composition of claim 2 wherein the base is selected from the group consisting of monomeric nitrogen compounds, polymeric nitrogen compounds, organic amines, organic ammonium hydroxides, salts thereof with organic acids, and mixtures thereof.

4-5. (canceled)

6. The photoresist composition of claim 1 wherein the polymer has an absorption coefficient of less than about 5.0 μm⁻¹ at a wavelength of about 157 nm.

7-13. (canceled)

14. The photoresist composition of claim 1 wherein the polymer comprises
(i) a repeat unit derived from at least one ethylenically unsaturated compound comprising a vinyl ether functional group and a fluoroalcohol functional group and having the structure:
C(R⁶⁰)(R⁶¹)═C(R⁶²)—O-D-C(R_{f})(R_{f}′)OH
wherein each of R⁶⁰, R⁶¹, and R⁶² independently is a hydrogen atom, or an alkyl group ranging from 1 to about 3 carbon atoms; D is at least one atom that links the vinyl ether functional group through an oxygen atom to a carbon atom of the fluoroalcohol functional group; R_{f} and R_{f}′ are the same or different fluoroalkyl groups containing from 1 to about 10 carbon atoms or taken together are (CF₂)ₙ wherein n is an integer ranging from 2 to about 10; and
(ii) a repeat unit derived from at least one ethylenically unsaturated compound having the structure:
(H)(R⁵⁷)C═C(R⁵⁸)(CN)
wherein R⁵⁷ is a hydrogen atom or cyano group; R⁵⁸ is an alkyl group ranging from 1 to about 8 carbon atoms, CO₂R⁵⁹ group wherein R⁵⁹ is an alkyl group ranging from 1 to about 8 carbon atoms, or hydrogen atom; and
(iii) a repeat unit derived from at least one ethylenically unsaturated compound comprising an acidic group.

15. (canceled)

16. A process for preparing a photoresist image on a substrate comprising, in order:
(X) imagewise exposing the photoresist layer to form imaged and non-imaged areas, wherein the photoresist layer is prepared from a photoresist composition comprising:
(A) a nitrile/fluoroalcohol-containing polymer;
(B) a photoactive component; and
(C) a functional compound selected from the group consisting of a base or a surfactant; and
(Y) developing the exposed photoresist layer having imaged and non-imaged areas to form the relief image on the substrate.

17. The process of claim 16 wherein the functional compound is a base with a pKₐ of 5 or greater.

18. The process of claim 17 wherein the base is selected from the group consisting of monomeric nitrogen compounds, polymeric nitrogen compounds, organic amines, organic ammonium hydroxides, salts thereof with organic acids, and mixtures thereof.

19-20. (canceled)

21. The process of claim 16 wherein the polymer has an absorption coefficient of less than 5.0 μm⁻¹ at a wavelength of 157 nm.

22. (canceled)

23. The photoresist composition of claim 1 further comprising a solvent.

24. A coated substrate for semiconductor manufacture comprising a substrate having on a surface thereof a coating of the photoresist composition of any one of claims 1 2, 3, 6, 14 and 23.

25. The coated substrate of claim 24 wherein the substrate comprises silicon, silicon oxide or silicon nitride.

26. The coated substrate of claim 24 wherein the substrate is primed.

27. The coated substrate of claim 26 wherein the substrate is primed with hexamethyldisilazane.

28. The coated substrate of claim 24 wherein the photoresist composition is coated onto the surface of the substrate by spin coating.

29. A photoresist composition comprising:
(A) a polymer selected from the group consisting of:
(a) a fluorine-containing copolymer comprising a repeat unit derived from at least one ethylenically unsaturated compound characterized in that the at least one ethylenically unsaturated compound is polycyclic;
(b) a branched polymer containing protected acid groups, said polymer comprising one or more branch segment(s) chemically linked along a linear backbone segment;
(c) a fluoropolymer having at least one fluoroalcohol group having the structure:
—C(R_{f})(R_{f}′)OH
wherein R_{f} and R_{f}′ are the same or different fluoroalkyl groups of from 1 to about 10 carbon atoms or taken together are (CF₂)ₙ wherein n is 2 to about 10; and
(d) a nitrile/fluoroalcohol-containing polymer; and
(B) at least one photoactive component that is chemically bonded to the polymer selected from the group consisting of (a) to (d); and
(C) a functional compound selected from the group consisting of a base and a surfactant.

30. A process for preparing a photoresist image on a substrate comprising, in order:
(X) imagewise exposing the photoresist layer to form imaged and non-imaged areas, wherein the photoresist layer is prepared from a photoresist composition comprising:
(A) a polymer selected from the group consisting of
(a) a fluorine-containing copolymer comprising a repeat unit derived from at least one ethylenically unsaturated compound characterized in that the at least one ethylenically unsaturated compound is polycyclic;
(b) a branched polymer containing protected acid groups, said polymer comprising one or more branch segment(s) chemically linked along a linear backbone segment
(c) a fluoropolymer having at least one fluoroalcohol group having the structure:
—C(R_{f})(R_{f}′)OH
wherein R_{f} and R_{f}′ are the same or different fluoroalkyl groups of from 1 to about 10 carbon atoms or taken together are (CF₂)ₙ wherein n is 2 to about 10; and
(d) a nitrile/fluoroalcohol-containing polymer; and
(B) a photoactive component that is chemically bonded to the polymer selected from the group consisting of (a) to (d); and
(C) a functional compound selected from the group consisting of a base or a surfactant; and
(Y) developing the exposed photoresist layer having imaged and non-imaged areas to form the relief image on the substrate.

31. A coated substrate for semiconductor manufacture comprising a substrate having on a surface thereof a coating of the photoresist composition of claim 29.

32. The photoresist composition of claim 1, wherein the nitrile/fluoroalcohol-containing polymer is prepared from a substituted or unsubstituted vinyl ether.

33. The process of claim 16 wherein the nitrile/fluoroalcohol-containing polymer is prepared from a substituted or unsubstituted vinyl ether.

34. The photoresist composition of claim 1, wherein the polymer is derived from at least one ethylenically unsaturated compound containing a fluoroalcohol functional group having the structure:
—C(R_{f})(R_{f}′)OH
wherein R_{f} and R_{f}′ are the same or different fluoroalkyl groups of from 1 to about 10 carbon atoms or taken together are (CF₂)ₙ wherein n is 2 to about 10.
